(19) United States
(12) Patent Application Publication
(10) Pub. No.: US 2026/0212909 A1
(43) Pub. Date: Jul. 23, 2026

(54) MEMORY DEVICE AND MEMORY SYSTEM

(71) Applicant: SAMSUNG ELECTRONICS CO., LTD., Suwon-si (KR)

(72) Inventor: Youngjae KIM, Suwon-si (KR)

(73) Assignee: SAMSUNG ELECTRONICS CO., LTD., Suwon-si (KR)

(21) Appl. No.: 19/421,322

(22) Filed: Dec. 16, 2025

(30) Foreign Application Priority Data
Jan. 22, 2025 (KR) 10-2025-0009820

(51) Int. Cl. G11C 11/4074; G11C 11/4078; G11C 11/409

(52) U.S. Cl. CPC G11C 11/4074; G11C 11/4078; G11C 11/409

(57) ABSTRACT

A memory device includes a power gating circuit for connecting a peripheral circuit to or disconnecting the peripheral circuit from a power supply voltage line in response to a power gating enable signal. The power gating circuit may include a boosting control circuit configured to, when a command indicates a standby mode, boost a gate voltage of a positive power gating switch to a first voltage level during a first stage and then boost the gate voltage of the positive power gating switch to a second voltage level during a second stage.

### CROSS-REFERENCE TO RELATED APPLICATION

This application is based on and claims priority under 35 U.S.C. § 119 to Korean Patent Application No. 10-2025-0009820, filed on Jan. 22, 2025, in the Korean Intellectual Property Office, the disclosure of which is incorporated by reference herein in its entirety.

### BACKGROUND

The inventive concept relates to a memory device, and more particularly, to a power gating operation of a memory device.

In recent years, there have been increasing demands for both high performance and low power consumption in electronic equipment. In particular, semiconductor memory devices are important components in battery-based systems, such as mobile equipment, and the power consumption of a memory device may have a significant impact on the power efficiency of a system as a whole.

The power consumed by memory devices is mainly classified into operating power and leakage power. The leakage power is continuously consumed even when the memory devices are in an inactive state and tends to increase as sizes of the semiconductor devices decrease. Therefore, reduction of the leakage current is becoming an increasingly important issue in designing memory devices.

Among several technologies for reducing the leakage current, power gating is one of the widely used techniques. The power gating reduces the leakage current in the inactive state by cutting off or limiting power to a specific part of a circuit and may thus be effective in improving the power efficiency of memory devices.

However, power gating methods according to the related art have limitations, such as power consumption and operating delays that occur during voltage switching processes, and thus, improved design and implementation methods for solving these limitations are required.

### SUMMARY

The inventive concept provides a memory device and a memory system capable of reducing the power required for a power gating operation.

According to an aspect of the inventive concept, there is provided a memory device including a memory cell array including memory cells, a peripheral circuit configured to transmit a plurality of signals for writing or reading data to the memory cells, a control logic circuit configured to output a power gating enable signal, and a power gating circuit configured to, in response to the power gating enable signal, connect the peripheral circuit to or disconnect the peripheral circuit from a power supply voltage line. The power gating circuit includes a positive power gating switch connected between the peripheral circuit and the power supply voltage line and a boosting control circuit configured to boost a gate voltage of the positive power gating switch to a first voltage level during a first stage and then boost the gate voltage of the positive power gating switch to a second voltage level higher than the first voltage level during a second stage after the first stage, to allow the memory device to operate in a standby mode.

According to another aspect of the inventive concept, there is provided a memory device including a memory cell array including memory cells, a peripheral configured to transmit a plurality of signals for writing or reading data to the memory cells, a control logic circuit configured to output a power gating enable signal, and a power gating circuit configured to, in response to the power gating enable signal, connect the peripheral circuit to or disconnect the peripheral circuit from a ground voltage line. The power gating circuit includes a negative power gating switch connected between the peripheral circuit and the ground voltage line and a dropping control circuit configured to drop a gate voltage of the negative power gating switch to a first voltage level during a first stage and then drop the gate voltage of the negative power gating switch to a second voltage level lower than the first voltage level during a second stage after the first stage, to allow the memory device to operate in a standby mode.

According to another aspect of the inventive concept, there is provided a memory system including a host device configured to transmit a command indicating a standby mode and a memory device configured to operate in the standby mode in response to the command. The memory device includes a memory cell array including memory cells, a peripheral circuit configured to transmit a plurality of signals for writing or reading data to the memory cell, a control logic circuit configured to output a power gating enable signal in response to the command, and a power gating circuit configured to, in response to the power gating enable signal, connect the peripheral circuit to or disconnect the peripheral circuit from a power supply voltage line. The power gating circuit includes a positive power gating switch connected between the peripheral circuit and the power supply voltage line and a boosting control circuit configured to boost a gate voltage of the positive power gating switch to a first voltage level during a first stage and then boost the gate voltage of the positive power gating switch to a second voltage level higher than the first voltage level during a second stage after the first stage.

### BRIEF DESCRIPTION OF THE DRAWINGS

Embodiments will be more clearly understood from the following detailed description taken in conjunction with the accompanying drawings in which:

FIG. 1 is a block diagram of a memory system according to an embodiment;

FIG. 2 is a block diagram of a memory device according to an embodiment;

FIG. 3 is a diagram of a power gating circuit and a peripheral circuit that are included in a memory device according to an embodiment;

FIG. 4 is a timing chart of a power gating circuit according to an embodiment;

FIG. 5 is a block diagram showing an example of a boosting control circuit according to the inventive concept;

FIG. 6 is a diagram of an equivalent circuit according to an example of the boosting control circuit of FIG. 5;

FIG. 7A shows an equivalent circuit according to an example of a pulse generating circuit of FIG. 6, and FIG. 7B is a timing chart of the equivalent circuit;

FIG. 8A shows an equivalent circuit according to an example of a delay circuit of FIG. 6, and FIG. 8B is a timing chart of the equivalent circuit;

FIG. 9 is a timing chart of the boosting control circuit of FIG. 6;

FIG. 10 is a block diagram showing an example of a dropping control circuit according to the inventive concept;

FIG. 11 is a diagram of an equivalent circuit according to an example of the dropping control circuit of FIG. 10;

FIG. 12A shows an equivalent circuit according to an example of a pulse generating circuit of FIG. 11, and FIG. 12B is a timing chart of the equivalent circuit;

FIG. 13A shows an equivalent circuit according to an example of a delay circuit of FIG. 11, and FIG. 13B is a timing chart of the equivalent circuit;

FIG. 14 is a timing chart of the dropping control circuit of FIG. 11;

FIG. 15 is a block diagram showing another example of a boosting control circuit according to the inventive concept;

FIG. 16 is a diagram showing an equivalent circuit according to an example of the boosting control circuit of FIG. 15;

FIG. 17A shows an equivalent circuit according to an example of a delay circuit of FIG. 16, and FIG. 17B is a timing chart of the equivalent circuit;

FIGS. 18A and 18B are diagrams illustrating a voltage control circuit of FIG. 16;

FIG. 19 is a timing chart of the boosting control circuit of FIG. 16;

FIG. 20 is a block diagram showing another example of a dropping control circuit according to the inventive concept;

FIG. 21 is a diagram showing an equivalent circuit according to an example of the dropping control circuit of FIG. 20;

FIGS. 22A and 22B are diagrams illustrating a voltage control circuit of FIG. 20;

FIG. 23 is a timing chart of the dropping control circuit of FIG. 21; and

FIG. 24 is a block diagram of a system and illustrates an electronic product including a memory device according to embodiments.

### DETAILED DESCRIPTION OF THE EMBODIMENTS

Hereinafter, various embodiments are described with reference to the accompanying drawings. The same reference numerals are given to the same elements in the drawings, and repeated descriptions thereof are omitted.

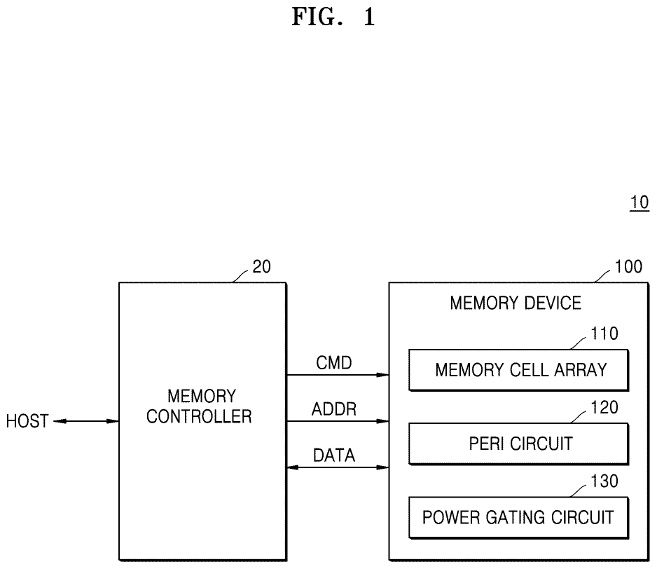

FIG. 1 is a block diagram of a memory system 10 according to an embodiment.

The memory system 10 may be a computing device such as an integrated circuit, an electronic device or system, a smartphone, a tablet personal computer (PC), a computer, a server, a workstation, a portable communication terminal, a personal digital assistant (PDA), a portable multimedia player (PMP), and other appropriate computers, a virtual machine or a virtual computing device thereof, and the like. Alternatively, the memory system 10 may represent some components of a computing system, such as a graphics card. According to an embodiment, the memory system 10 may be provided as an unbuffered dual in-line memory module (UDIMM), a registered DIMM (RDIMM), a load reduced DIMM (LRDIMM), a fully buffered DIMM (FBDIMM), or a small outline DIMM (SODIMM).

Also, the memory system 10 or a data processing system including the memory system 10 may be provided as a PC, a data server, a cloud system, an artificial intelligence server, a network-attached storage (NAS), an Internet of Things (IoT) device, or a portable electronic product. Also, when the data processing system is provided as the portable electronic product, the data processing system may include a laptop computer, a mobile phone, a smartphone, a tablet PC, a PDA, an enterprise digital assistant (EDA), a digital still camera, a digital video camera, an audio device, a PMP, a personal navigation device (PND), an MP3 player, a handheld game console, an e-book, a wearable device, etc.

Referring to FIG. 1, the memory system 10 may include a memory device 100 and a memory controller 20. The memory controller 20 and the memory device 100 each may include an interface circuit (not shown) to communicate various signals. For example, the memory controller 20 may provide a clock and a command/address CMD/ADDR to the memory device 100 and access data DATA of the memory device 100.

Referring to FIG. 1, the memory device 100 may include a memory cell array 110, a peripheral circuit 120, and a power gating circuit 130.

The memory cell array 110 may include a plurality of word lines, a plurality of bit lines, and a plurality of memory cells formed at intersections between the word lines and the bit lines. The memory cells of the memory cell array 110 may include volatile memory cells (e.g., dynamic random-access memory (DRAM) cells or static random-access memory (SRAM) cells), non-volatile memory cells (e.g., flash memory cells, resistive random-access memory (ReRAM) cells, phase-change random access memory (PRAM) cells, or magnetic random-access memory (MRAM) cells), or other types of memory cells.

The peripheral circuit 120 may provide the plurality of memory cells with a plurality of signals for accessing data, such as writing or reading data. The peripheral circuit 120 may be located around the memory cell array 110 on a semiconductor substrate and provide signals necessary for data access to the memory cell array in the memory cell array 110.

In an embodiment, the peripheral circuit 120 may include a command/address decoder (not shown), perform a decoding operation on the command/address CMD/ADDR, and control an operation of the memory device 100 on the basis of the decoding result.

The power gating circuit 130 may be connected between the peripheral circuit 120 and a power supply voltage line (or a ground voltage line). The power gating circuit 130 may allow or block providing the power supply voltage (or the ground voltage) to the peripheral circuit 120 depending on the mode of the memory device 100 (the active mode ACT or the standby mode STBY). That is, the power gating circuit 130 may selectively supply power to the peripheral circuit 120 depending on the mode of the memory device 100.

When the memory device 100 operates in the active mode ACT, the power gating circuit 130 may provide the power supply voltage (or the ground voltage) to the peripheral circuit 120 so that the peripheral circuit 120 operates.

When the memory device 100 operates in the standby mode STBY, the power gating circuit 130 may block providing the power supply voltage (or the ground voltage) to the peripheral circuit 120 so that the peripheral circuit 120 does not operate.

That is, the memory device 100 may include the power gating circuit 130 to reduce unnecessary power consumption due to leakage current in an idle state (the standby mode STBY).

Also, the memory device 100 may include DRAM, such as double data rate synchronous dynamic random-access memory (DDR SDRAM), low power double data rate (LPDDR) SDRAM, graphics double data rate (GDDR) SDRAM, Rambus dynamic random-access memory (RDRAM), DDR2 SDRAM, DDR3 SDRAM, and DDR4 SDRAM. However, the embodiments are not limited thereto, and the memory device 100 may include, for example, non-volatile memory, such as flash memory, MRAM, spin-transfer torque MRAM, conductive bridging RAM (CBRAM), ferroelectric RAM (FeRAM), PRAM, and ReRAM.

Also, the memory device 100 may correspond to a single semiconductor chip or may be configured to correspond to a single channel in a memory device including a plurality of channels having independent interfaces. Also, the memory device 100 may have a configuration corresponding to a memory module. Also, a memory module may include a plurality of memory chips, and the memory device 100 of FIG. 1 may correspond to a single memory chip mounted on a module board.

The memory controller 20 may access the memory device 100 in response to a request from a host HOST, and the memory controller 20 may communicate with the host HOST via various protocols. According to embodiments, the memory controller 20 may correspond to the host HOST, or the memory controller 20 may correspond to a component provided inside the host HOST. The host HOST and the memory device 100 may constitute a data processing system, and accordingly, the memory system 10 may correspond to the data processing system or be defined as a component provided in the data processing system.

In response to read/write requests from the host HOST, the memory controller 20 may control the memory device 100 to read data stored in the memory device 100 or program data into the memory device 100. Specifically, the memory controller 20 may provide a command CMD, an address ADDR, and a control signal to the memory device 100, thereby controlling programming, reading, and erasing operations with respect to the memory device 100. Also, data DATA for programming and data DATA to be read may be exchanged between the memory controller 20 and the memory device 100.

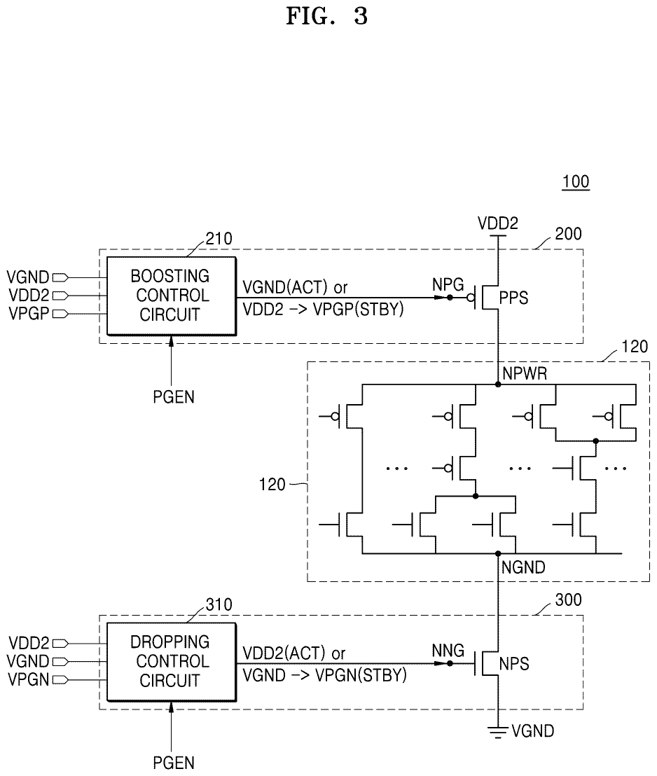

According to the inventive concept, when entering the idle state (the standby mode STBY), a gate voltage level of a positive power gating switch PPS in FIG. 3 is not raised (boosted) to a positive power gating voltage VPGP at once, but is raised to a second power supply voltage VDD2 in an intermediate stage and then raised to the positive power gating voltage VPGP. This may reduce power consumed by a power gating operation of a first power gating circuit 200.

According to the inventive concept, when entering the idle state (the standby mode STBY), a gate voltage level of a negative power gating switch NPS in FIG. 3 is not lowered (dropped) to a negative power gating voltage VPGN at once, but is lowered to a ground voltage VGND in an intermediate stage and then lowered to the negative power gating voltage VPGN. This reduces power consumed by a power gating operation of a second power gating circuit 300.

Since power is proportional to the square of the voltage, the power consumed by the power gating operation may be reduced by raising (or lowering) the voltage level of the positive power gating switch PPS (or the negative power gating switch NPS) twice instead of once. For example, when voltage is raised from 0 V to 1.2 V, the power consumption when the voltage is raised twice, from 0 V to 1 V and then from 1 V to 1.2 V, is less than the power consumption when the voltage is raised from 0 V to 1.2 V all at once (1.2²>1²+0.2²).

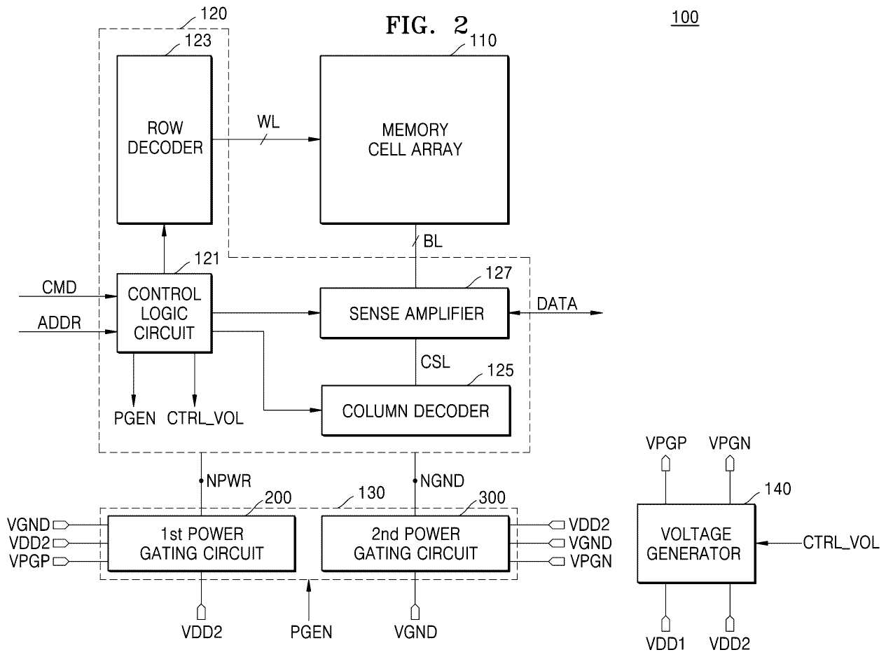

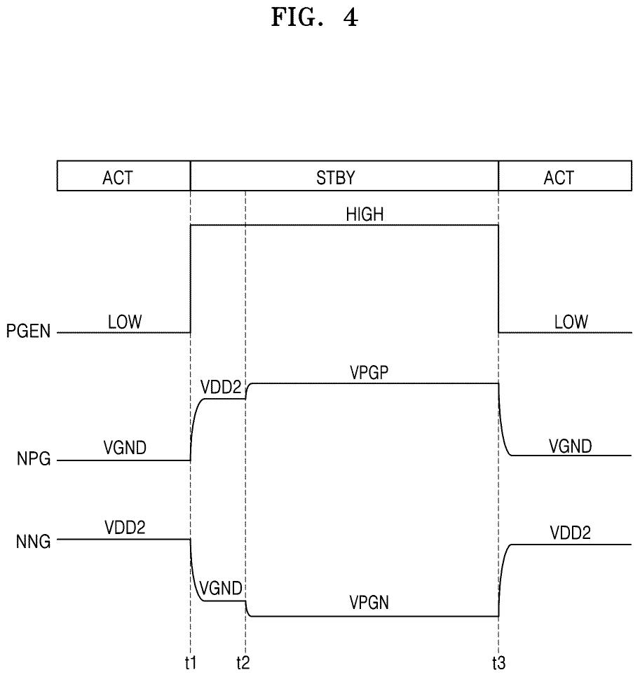

FIG. 2 is a block diagram of the memory device 100 according to an embodiment. FIG. 3 is a diagram showing a power gating circuit and a peripheral circuit that are included in the memory device 100 according to an embodiment. FIG. 4 is a timing chart of the power gating circuit according to an embodiment.

FIG. 2 is a diagram conceptually showing the configuration of the memory device 100 implemented as a DRAM.

Referring to FIG. 2, the memory device 100 may include a memory cell array 110, a peripheral circuit 120, a power gating circuit 130, and a voltage generator 140. FIG. 2 illustrates that the power gating circuit 130 and the voltage generator 140 are separate from the peripheral circuit 120, but the embodiment is not limited thereto. According to embodiments, the power gating circuit 130 and the voltage generator 140 may be provided inside the peripheral circuit 120.

The peripheral circuit 120 may include a control logic circuit 121, a row decoder 123, a column decoder 125, and a sense amplifier 127. The peripheral circuit 120 may further include an address buffer (not shown), an input/output gating circuit (not shown), and a data input/output circuit (not shown).

The memory cell array 110 may be connected to the row decoder 123 via word lines WL and connected to the sense amplifier 127 via bit lines BL. The memory cell array 110 may include a plurality of bank memory arrays. Each of the plurality of bank memory arrays may include a plurality of word lines WL, a plurality of bit lines BL, and a plurality of memory cells formed at intersections between the word lines WL and the bit lines BL.

The row decoder 123 may include bank row decoders respectively connected to the plurality of bank memory arrays, and the column decoder 125 may include bank column decoders respectively connected to the plurality of bank memory arrays. The sense amplifier 127 may include sense amplifiers respectively connected to the plurality of bank memory arrays.

One bank memory array, one bank row decoder, one bank column decoder, and one sense amplifier may constitute one bank. Here, the one bank memory array, the one bank row decoder, the one bank column decoder, and the one sense amplifier may be referred to as core circuits of the corresponding bank. According to embodiments, the memory device 100 may include various numbers of banks.

The control logic circuit 121 may include an address buffer (not shown). The address buffer (not shown) may receive the address ADDR, including a row address and a column address, from the memory controller 20 (FIG. 1) connected to the memory device 100. Also, the address buffer (not shown) may receive a bank address and provide the bank address to the control logic circuit 121, provide the received row address to the row decoder 123, and provide the received column address to the column decoder 125. The control logic circuit 121 may generate bank control signals in response to the bank address. In response to the bank control signals, a bank row decoder, corresponding to the bank address, among the plurality of bank row decoders may be activated, and a bank column decoder, corresponding to the bank address, among the plurality of bank column decoders may be activated. In an embodiment of FIG. 2, it is described that the control logic circuit 121 includes the address buffer (not shown), but the embodiment is not limited thereto. According to embodiments, the address buffer (not shown) may be provided outside the control logic circuit 121 and thus be separated from the control logic circuit 121.

The control logic circuit 121 may control all operations of the memory device 100. The control logic circuit 121 may generate control signals for performing a write operation and/or a read operation of the memory device 100. Also, the control logic circuit 121 may output a voltage control signal CTRL_VOL and/or a power gating enable signal PGEN.

The voltage generator 140 may generate various types of voltages for performing program, read, and erase operations on the basis of the voltage control signal CTRL_VOL. The voltage generator 140 may be formed as a low dropout regulator (LDO) or a charge pump circuit, etc.

Also, the voltage generator 140 may generate voltages for the power gating operation. Referring to FIG. 2, the voltage generator 140 may generate a negative power gating voltage VPGN and the positive power gating voltage VPGP on the basis of a first power supply voltage VDD1 and/or the second power supply voltage VDD2.

Here, the first power supply voltage VDD1 may include a voltage that is supplied to an internal core logic of the memory device 100, and the second power supply voltage VDD2 may include a voltage that is supplied to a memory cell and an input/output interface. For example, the first power supply voltage VDD1 may be 1.0 V, and the second power supply voltage VDD2 may be 1.8 V. Also, the positive power gating voltage VPGP may be higher than the second power supply voltage VDD2, and the negative power gating voltage VPGN may be lower than a ground voltage VGN (e.g., 0 V).

Also, the control logic circuit 121 may include a mode register for setting a plurality of operating options of the memory device 100 and a command decoder for decoding the command CMD received from a memory controller.

Also, in response to the command CMD, the control logic circuit 121 may control the operations of the memory device 100 so that the memory device 100 operates in the active mode ACT or the standby mode STBY. Here, the active mode ACT represents a state in which the memory device 100 is operating normally and processing data, and the memory device 100 in the active mode ACT may perform the write operation and/or the read operation. The standby mode STBY represents a state in which the memory device 100 is in an idle state, and the memory device 100 in the standby mode STBY may maintain data and not perform the write operation and the read operation.

For example, the control logic circuit 121 may output the power gating enable signal PGEN having a logic low level in response to the command CMD indicating the active mode ACT. The power gating circuit 130 may provide the second power supply voltage VDD2 (or the ground voltage VGND) to the peripheral circuit 120 in response to the power gating enable signal PGEN having the logic low level. Also, the control logic circuit 121 may output the power gating enable signal PGEN having a logic high level in response to the command CMD indicating the standby mode STBY. The power gating circuit 130 may block the second power supply voltage VDD2 (or the ground voltage VGND), provided to the peripheral circuit 120, in response to the power gating enable signal PGEN having the logic high level.

The sense amplifier 127 may be connected to an input/output gating circuit (not shown), and the input/output gating circuit (not shown) may be connected to a data input/output circuit (not shown). The sense amplifier 127 may sense data stored in the memory cell and transmit the sensed data to the data input/output circuit (not shown) so that the data may be output to the memory controller via data pad(s). The data input/output circuit (not shown) may receive data, which is to be written to the memory cells, from the memory controller via the data pad(s) and transmit the data to the memory cell array 110. The input/output gating circuit (not shown) may output read data by using a data line amplifier that receives and amplifies the data sensed by the sense amplifier 127. The read data may be output to the memory controller via the data pad(s). The input/output gating circuit (not shown) may include circuits for gating input/output data DATA or DQ, a column selection circuit, input data mask logic, read data latches for storing read data output from the bank memory arrays, and write drivers for writing data on the bank memory arrays.

The read data output from one bank memory array may be sensed by the corresponding sense amplifier and stored in the read data latches. The write data, which is to be written on the memory cell array of one bank memory array, may be provided from the memory controller 20 (FIG. 1) to the data input/output circuit (not shown). The data provided to the data input/output circuit (not shown) may be written on the bank memory array via the write driver.

The memory device 100 may include the power gating circuit 130 that selectively supplies power to the peripheral circuit 120. The power gating circuit 130 may selectively supply power to each of the control logic circuit 121, the row decoder 123, the column decoder 125, the sense amplifier 127, the address buffer (not shown), the input/output gating circuit (not shown), and/or the data input/output circuit (not shown), which are provided in the peripheral circuit 120.

Also, the power gating circuit 130 may allow or block providing the power supply voltage (or the ground voltage) to the peripheral circuit 120 depending on the mode of the memory device 100 (the active mode ACT or the standby mode STBY). That is, the power gating circuit 130 may selectively supply power to the peripheral circuit 120 depending on the mode of the memory device 100.

Referring to FIGS. 2 and 3, the power gating circuit 130 may include the first power gating circuit 200 and the second power gating circuit 300. Referring to FIG. 3, the first power gating circuit 200 may include the positive power gating switch PPS and a boosting control circuit 210, and the second power gating circuit 300 may include the negative power gating switch NPS and a dropping control circuit 310.

Switches described below may include a metal oxide silicon field effect transistor (MOSFET), but the inventive concept is not limited thereto. For example, the positive power gating switch PPS may be formed as a p-channel metal-oxide semiconductor (PMOS) transistor, and the negative power gating switch NPS may be formed as an n-channel metal-oxide semiconductor (NMOS) transistor.

Referring to FIGS. 2 and 3, the first power gating circuit 200 may be connected between the peripheral circuit 120 and a line of the second power supply voltage VDD2. A source terminal of the positive power gating switch PPS may be connected to the line of the second power supply voltage VDD2, and a drain terminal of the positive power gating switch PPS may be connected to the peripheral circuit 120 via a node NPWR. A gate terminal of the positive power gating switch PPS may be connected to the boosting control circuit 210 via a node NPG.

Here, the node NPWR may refer to a head node of the peripheral circuit 120 and represent a node from which current from the line of the second power supply voltage VDD2 begins to be distributed to the peripheral circuit 120. That is, the node NPWR may represent a start point for the current that flows in the peripheral circuit 120.

In response to the power gating enable signal PGEN, the boosting control circuit 210 may adjust a voltage level of the node NPG connected to the gate terminal of the positive power gating switch PPS. The boosting control circuit 210 may be connected to a line of the ground voltage VGND, the line of the second power supply voltage VDD2, and/or a line of the positive power gating voltage VPGP.

Referring to FIG. 3, in the active mode ACT, the boosting control circuit 210 may turn on the positive power gating switch PPS by adjusting the voltage level of the node NPG to the ground voltage VGND. Accordingly, the line of the second power supply voltage VDD2 may be connected to the peripheral circuit 120.

On the other hand, in the standby mode STBY, the boosting control circuit 210 may turn off the positive power gating switch PPS by adjusting the voltage level of the node NPG to the second power supply voltage VDD2 and then further adjusting the voltage level to the positive power gating voltage VPGP. Accordingly, the line of the second power supply voltage VDD2 may be disconnected from the peripheral circuit 120.

Referring to FIGS. 3 and 4, at a point in time t1, the control logic circuit 121 may provide the power gating enable signal PGEN having the logic high level to the boosting control circuit 210 in response to the command CMD indicating the standby mode STBY. At the point in time t1, the boosting control circuit 210 responds to the power gating enable signal PGEN having the logic high level. From the point in time t1, the boosting control circuit 210 may raise the voltage level of the node NPG to the second power supply voltage VDD2. From a point in time t2 delayed by a predetermined amount of time after the point in time t1, the boosting control circuit 210 may raise the voltage level of the node NPG to the positive power gating voltage VPGP. Subsequently, at a point in time t3, the control logic circuit 121 may provide the power gating enable signal PGEN having the logic low level to the boosting control circuit 210 in response to the command CMD indicating the active mode ACT. From the point in time t3, the boosting control circuit 210 may lower the voltage level of the node NPG to the ground voltage VGND in response to the power gating enable signal PGEN having the logic low level.

According to the inventive concept, the voltage level of the node NPG is not raised to the positive power gating voltage VPGP at once, but is raised to the second power supply voltage VDD2 in an intermediate stage and then raised to the positive power gating voltage VPGP. This may reduce the power consumed by the power gating operation of the first power gating circuit 200.

Referring to FIGS. 2 and 3, the second power gating circuit 300 may be connected between the peripheral circuit 120 and the line of the ground voltage VGND. A source terminal of the negative power gating switch NPS may be connected to the line of the ground voltage VGND, and a drain terminal of the negative power gating switch NPS may be connected to the peripheral circuit 120 via a node NGND. A gate terminal of a negative power gating switch NPS may be connected to the dropping control circuit 310 via a node NNG.

Here, the node NGND may refer to a foot node of the peripheral circuit 120 and represent a node through which the current from the peripheral circuit 120 passes just before escaping to the line of the ground voltage VGND. That is, the node NGND may represent an end point for the current that flows in the peripheral circuit 120.

In response to the power gating enable signal PGEN, the dropping control circuit 310 may adjust a voltage level of the node NNG connected to the gate terminal of the negative power gating switch NPS. The dropping control circuit 310 may be connected to the line of the second power supply voltage VDD2, the line of the ground voltage VGND, and/or a line of the negative power gating voltage VPGN.

Referring to FIG. 3, in the active mode ACT, the dropping control circuit 310 may turn on the negative power gating switch NPS by adjusting the voltage level of the node NNG to the second power supply voltage VDD2. Accordingly, the line of the ground voltage VGND may be connected to the peripheral circuit 120.

On the other hand, in the standby mode STBY, the dropping control circuit 310 may turn off the negative power gating switch NPS by adjusting the voltage level of the node NNG to the ground voltage VGND and then further adjusting the voltage level to the negative power gating voltage VPGN. Accordingly, the line of the ground voltage VGND may be disconnected from the peripheral circuit 120.

Referring to FIGS. 3 and 4, at the point in time t1, the control logic circuit 121 may provide the power gating enable signal PGEN having the logic high level to the dropping control circuit 310 in response to the command CMD indicating the standby mode STBY. At the point in time t1, the dropping control circuit 310 responds to the power gating enable signal PGEN having the logic high level. From the point in time t1, the dropping control circuit 310 may lower the voltage level of the node NNG to the ground voltage VGND. From the point in time t2 delayed by the predetermined amount of time after the point in time t1, the dropping control circuit 310 may lower the voltage level of the node NNG to the negative power gating voltage VPGN. Subsequently, at the point in time t3, the control logic circuit 121 may provide the power gating enable signal PGEN having the logic low level to the dropping control circuit 310 in response to the command CMD indicating the active mode ACT. From the point in time t3, the dropping control circuit 310 may raise the voltage level of the node NNG to the second power supply voltage VDD2 in response to the power gating enable signal PGEN having the logic low level.

According to the inventive concept, the voltage level of the node NNG is not lowered to the negative power gating voltage VPGN at once, but is lowered to the ground voltage VGND in an intermediate stage and then lowered to the negative power gating voltage VPGN. This may reduce the power consumed by the power gating operation of the second power gating circuit 300.

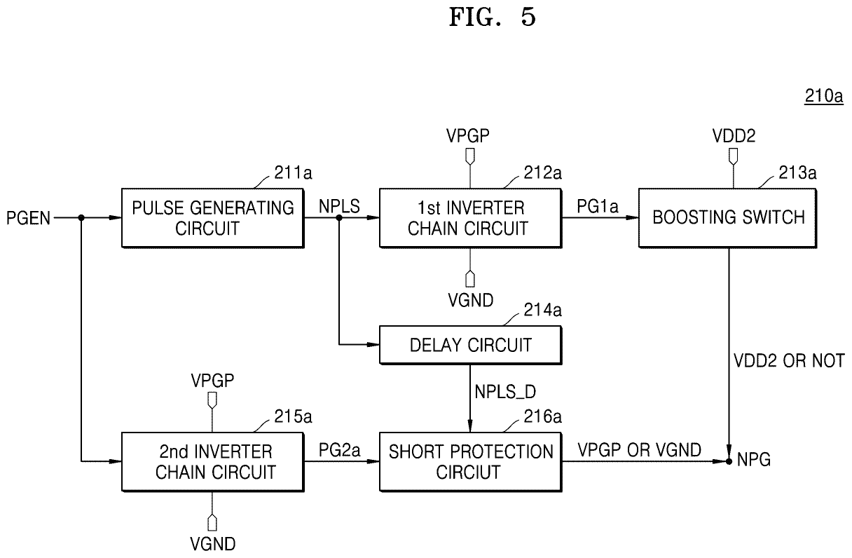

FIG. 5 is a block diagram of an example of a boosting control circuit 210a according to the inventive concept.

Referring to FIG. 5, the boosting control circuit 210a may include a pulse generating circuit 211a, a first inverter chain circuit 212a, a boosting switch 213a, a delay circuit 214a, a second inverter chain circuit 215a, and a short protection circuit 216a.

The pulse generating circuit 211a may output a pulse signal NPLS in response to the power gating enable signal PGEN. For example, when the power gating enable signal PGEN transitions from the logic low level to the logic high level, the pulse generating circuit 211a may output the pulse signal NPLS having the logic low level.

Each of the first inverter chain circuit 212a and the second inverter chain circuit 215a may include a plurality of inverter circuits that are connected to each other in series. Here, a positive power supply terminal of each of the inverter circuits may be connected to the line of the positive power gating voltage VPGP, and a negative power supply terminal of each of the inverter circuits may be connected to the line of the ground voltage VGND. The first inverter chain circuit 212a and the second inverter chain circuit 215a may output the positive power gating voltage VPGP or the ground voltage VGND according to a logic level of an input signal.

The first inverter chain circuit 212a may receive the pulse signal NPLS as an input signal and output the positive power gating voltage VPGP or the ground voltage VGND as a first power gating signal PG1a according to the logic level of the pulse signal NPLS.

The second inverter chain circuit 215a may receive the power gating enable signal PGEN as an input signal and output the positive power gating voltage VPGP or the ground voltage VGND as a second power gating signal PG2a according to the logic level of the power gating enable signal PGEN.

The boosting switch 213a may be connected between the line of the second power supply voltage VDD2 and the node NPG. The boosting switch 213a may be turned on or off in response to the first power gating signal PG1a. For example, the boosting switch 213a may be turned on in response to the first power gating signal PG1a having the level of the ground voltage VGND, and accordingly, the line of the second power supply voltage VDD2 may be connected to the node NPG. Also, the boosting switch 213a may be turned off in response to the first power gating signal PG1a having the level of the positive power gating voltage VPGP, and accordingly, the line of the second power supply voltage VDD2 may be disconnected from the node NPG.

The delay circuit 214a may receive the pulse signal NPLS as an input signal and output a delayed pulse signal NPLS_D. Here, the delayed pulse signal NPLS_D may represent a pulse signal having a form in which a period of time having a specific logic level of the pulse signal NPLS has been increased by a predetermined amount of time. For example, when the pulse signal NPLS has a logic low level, the delayed pulse signal NPLS_D may represent a pulse signal having a form in which a period of time having the logic low level of the pulse signal NPLS has been increased by a predetermined amount of time.

The short protection circuit 216a may be connected between the second inverter chain circuit 215a and the node NPG. The short protection circuit 216a may be turned on or off in response to the delayed pulse signal NPLS_D. For example, the short protection circuit 216a may be turned on in response to the delayed pulse signal NPLS_D having the logic high level, and accordingly, the second inverter chain circuit 215a may be connected to the node NPG. Accordingly, the short protection circuit 216a may provide the node NPG with the positive power gating voltage VPGP or the ground voltage VGND, which represents the voltage level of the second power gating signal PG2a.

Also, the short protection circuit 216a may be turned off in response to the delayed pulse signal NPLS_D having the logic low level, and accordingly, the second inverter chain circuit 215a may be disconnected from the node NPG. The short protection circuit 216a may prevent a short-circuit between the line of the positive power gating voltage VPGP connected to a positive power supply terminal of the second inverter chain circuit 215a and the line of the second power supply voltage VDD2 connected to the boosting switch 213a.

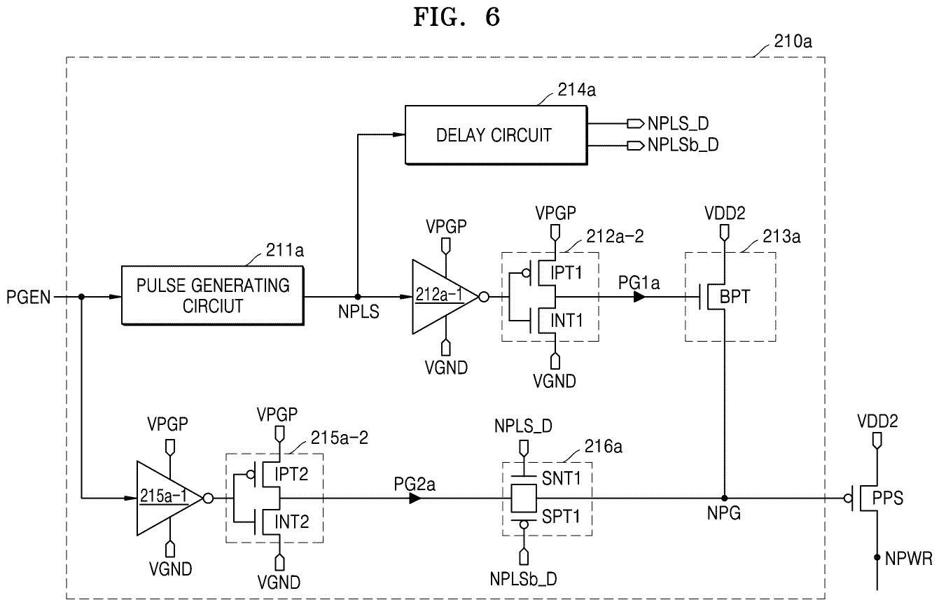

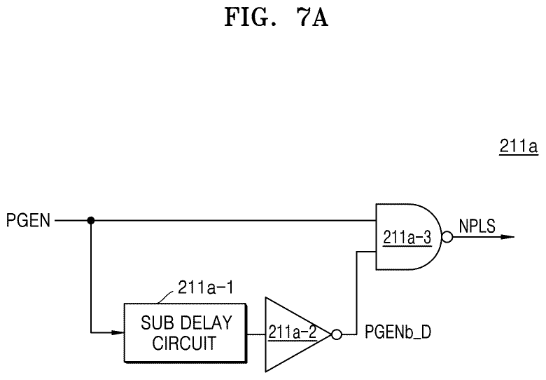

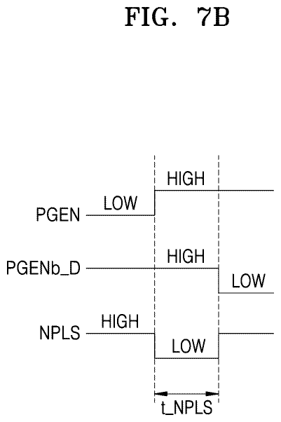

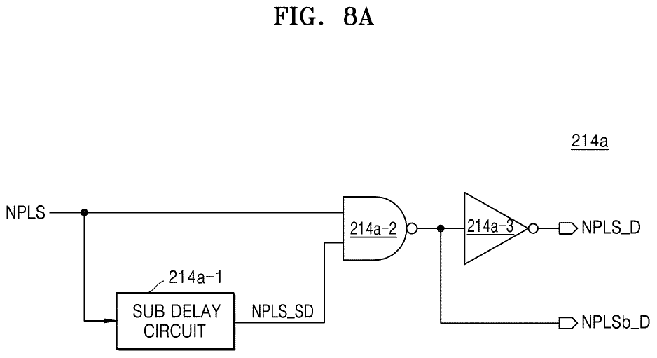

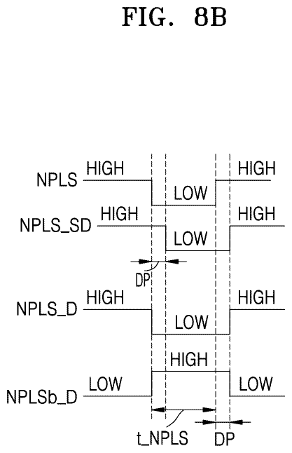

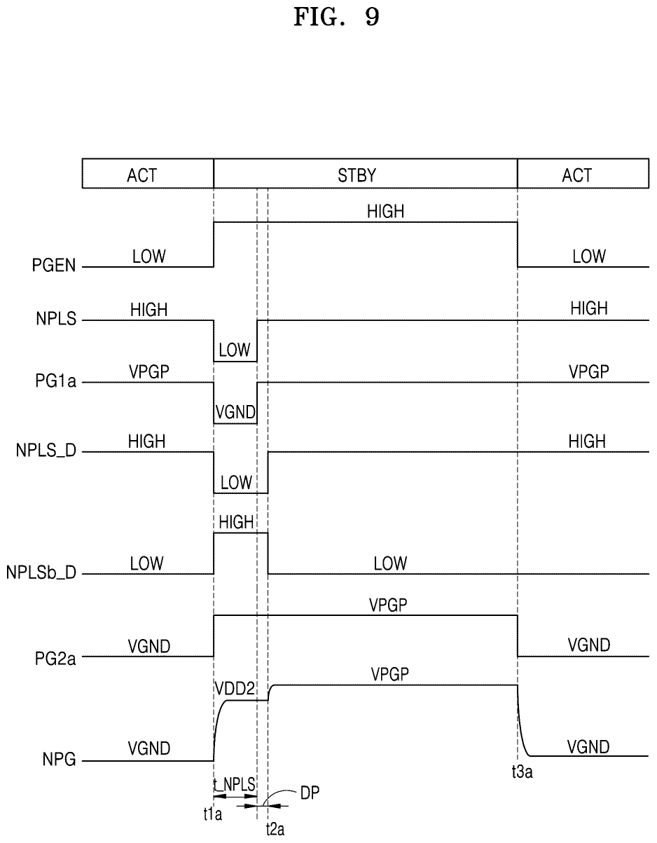

FIG. 6 is a diagram of an equivalent circuit according to an example of the boosting control circuit 210a of FIG. 5. FIG. 7A shows an equivalent circuit according to an example of the pulse generating circuit 211a of FIG. 6, and FIG. 7B is a timing chart of the equivalent circuit. FIG. 8A shows an equivalent circuit according to an example of the delay circuit 214a of FIG. 6, and FIG. 8B is a timing chart of the equivalent circuit. FIG. 9 is a timing chart of the boosting control circuit 210a of FIG. 6.

Prior to describing the boosting control circuit 210a of FIG. 6, the pulse generating circuit 211a and the delay circuit 214a are described first with reference to FIGS. 7A and 7B and FIGS. 8A and 8B.

Referring to FIG. 7A, the pulse generating circuit 211a may include a sub delay circuit 211a-1, an inverter circuit 211a-2, and a NAND logic circuit 211a-3.

The sub delay circuit 211a-1 may receive the power gating enable signal PGEN as an input signal and output a delayed power gating enable signal. The inverter circuit 211a-2 may receive the delayed power gating enable signal as an input signal and output a delayed inverted power gating enable signal PGENb_D. The NAND logic circuit 211a-3 may receive the power gating enable signal PGEN and the delayed inverted power gating enable signal PGENb_D as input signals and output the pulse signal NPLS.

The sub delay circuit 211a-1 may output, as an output signal, a signal having a form in which the input signal is delayed by a predetermined pulse time t_NPLS. The pulse time t_NPLS may be determined in advance by considering a response speed or power consumption, etc. according to characteristics of current in total circuits. Also, the sub delay circuit 211a-1 may be formed as an inverter chain circuit, etc., and the pulse time t_NPLS may be determined according to design parameters (e.g., the number of steps in the inverter chain, etc.).

Referring to FIG. 7B, when the power gating enable signal PGEN is continuously at a low level, the logic levels of both the delayed inverted power gating enable signal PGENb_D and the pulse signal NPLS may also be at the logic high level. When the power gating enable signal PGEN transitions from the logic low level to the logic high level, the delayed inverted power gating enable signal PGENb_D may transition from the logic high level to the logic low level after the pulse time t_NPLS has elapsed. Accordingly, the pulse signal NPLS may have the logic low level during the pulse time t_NPLS.

Referring to FIG. 8A, the delay circuit 214a may include a sub delay circuit 214a-1, a NAND logic circuit 214a-2, and an inverter circuit 214a-3.

The sub delay circuit 214a-1 may receive the pulse signal NPLS of FIG. 7A as an input signal and output a pulse signal NPLS_SD having a form in which all of the pulse signal NPLS is delayed by a delay time DP. The NAND logic circuit 214a-2 may receive the pulse signal NPLS and the delayed pulse signal NPLS_SD as input signals and output a delayed inverted pulse signal NPLSb_D. The inverter circuit 214a-3 may receive the delayed inverted pulse signal NPLSb_D as an input signal and output the delayed pulse signal NPLS_D.

The sub delay circuit 214a-1 may output, as an output signal, a signal having a form in which the input signal is delayed by a predetermined delay time DP. The delay time DP may be determined in advance by considering a response speed or power consumption, etc. according to characteristics of current in total circuits. Also, the sub delay circuit 214a-1 may be formed as an inverter chain circuit, etc., and the pulse time t_NPLS may be determined according to design parameters (e.g., the number of steps in the inverter chain, etc.).

Referring to FIG. 8B, the delayed pulse signal NPLS_D may represent a pulse signal having a form in which a period of time having a specific logic level of the pulse signal NPLS has been increased by the predetermined delay time DP. When the pulse signal NPLS has a logic low level, the delayed pulse signal NPLS_D may represent a pulse signal having a form in which a period of time having the logic low level of the pulse signal NPLS has been increased by the predetermined delay time DP. Unlike the delayed pulse signal NPLS_D, a transition point in time of the delayed pulse signal NPLS_SD from the logic high level to the logic low level may also be delayed by the delay time DP. That is, in the delayed pulse signal NPLS_D, the transition point in time from the logic high level to the logic low level is maintained, and only the transition point in time from the logic low level to the logic high level may be delayed by the delay time DP in addition to the pulse time t_NPLS. Accordingly, a period of time for which the delayed pulse signal NPLS_D remains at the logic low level may be increased by the delay time DP.

Returning to FIG. 6, the boosting control circuit 210a of FIG. 6 is described with reference to FIGS. 6 and 9.

Referring to FIG. 6, each of the first inverter chain circuit 212a and the second inverter chain circuit 215a may include two inverter circuits. However, the embodiment is not limited thereto, and the number of inverter circuits in the first and second inverter chain circuits 212a and 215a may vary according to embodiments. The number of inverter circuits may be determined by considering a response speed or power consumption, etc. according to characteristics of current in total circuits. Also, the inverter circuit may be formed as a complementary metal-insulator-semiconductor (CMOS) transistor and configured such that the NMOS transistor and the PMOS transistor in the inverter circuit operate in a complementary manner.

Referring to FIG. 6, the first inverter chain circuit 212a may include an inverter circuit 212a-1 and an inverter circuit 212a-2. The inverter circuit 212a-1 and the inverter circuit 212a-2 may be connected to each other in series. The inverter circuit 212a-1 may receive the pulse signal NPLS as an input signal, and the inverter circuit 212a-2 may output the positive power gating voltage VPGP or the ground voltage VGND as the first power gating signal PG1a according to the logic level of the pulse signal NPLS.

Referring to FIG. 6, the inverter circuit 212a-2 may include a PMOS transistor IPT1 and an NMOS transistor INT1. A source terminal of the PMOS transistor IPT1 may be connected to the line of the positive power gating voltage VPGP, a drain terminal of the PMOS transistor IPT1 may be connected to a gate terminal of a PMOS transistor BPT and a drain terminal of the NMOS transistor INT1, and a gate terminal of the PMOS transistor IPT1 may be connected to an output terminal of the inverter circuit 212a-1. A source terminal of the NMOS transistor INT1 may be connected to the line of the ground voltage VGND, the drain terminal of the NMOS transistor INT1 may be connected to the gate terminal of the PMOS transistor BPT and the drain terminal of the PMOS transistor IPT1, and a gate terminal of the NMOS transistor INT1 may be connected to the output terminal of the inverter circuit 212a-1.

Referring to FIG. 6, the second inverter chain circuit 215a may include an inverter circuit 215a-1 and an inverter circuit 215a-2. The inverter circuit 215a-1 and the inverter circuit 215a-2 may be connected to each other in series. The inverter circuit 215a-1 may receive the power gating enable signal PGEN as an input signal, and the inverter circuit 215a-2 may output the positive power gating voltage VPGP or the ground voltage VGND as the second power gating signal PG2a according to the logic level of the power gating enable signal PGEN.

Referring to FIG. 6, the inverter circuit 215a-2 may include a PMOS transistor IPT2 and an NMOS transistor INT2. A source terminal of the PMOS transistor IPT2 may be connected to the line of the positive power gating voltage VPGP, a drain terminal of the PMOS transistor IPT2 may be connected to the short protection circuit 216a and a drain terminal of the NMOS transistor INT2, and a gate terminal of the PMOS transistor IPT2 may be connected to an output terminal of the inverter circuit 215a-1. A source terminal of the NMOS transistor INT2 may be connected to the line of the ground voltage VGND, the drain terminal of the NMOS transistor INT2 may be connected to the short protection circuit 216a and the drain terminal of the PMOS transistor IPT2, and a gate terminal of the NMOS transistor INT2 may be connected to the output terminal of the inverter circuit 215a-1.

Referring to FIG. 6, the boosting switch 213a may include the PMOS transistor BPT. The PMOS transistor BPT may be connected between the line of the second power supply voltage VDD2 and the node NPG. The PMOS transistor BPT may be turned on or off in response to the first power gating signal PG1a. For example, the PMOS transistor BPT may be turned on in response to the first power gating signal PG1a having the level of the ground voltage VGND, and accordingly, the line of the second power supply voltage VDD2 may be connected to the node NPG. Also, the PMOS transistor BPT may be turned off in response to the first power gating signal PG1a having the level of the positive power gating voltage VPGP, and accordingly, the line of the second power supply voltage VDD2 may be disconnected from the node NPG.

Referring to FIG. 6, the short protection circuit 216a may include an NMOS transistor SNT1 and a PMOS transistor SPT1. A source terminal of the PMOS transistor SPT1 may be connected to an output terminal of the inverter circuit 215a-2 and a source terminal of the NMOS transistor SNT1, a drain terminal of the PMOS transistor SPT1 may be connected to the node NPG, and a gate terminal of the PMOS transistor SPT1 may be connected to a line of the delayed inverted pulse signal NPLSb_D. The source terminal of the NMOS transistor SNT1 may be connected to the output terminal of the inverter circuit 215a-2 and the source terminal of the PMOS transistor SPT1, a drain terminal of the NMOS transistor SNT1 may be connected to the node NPG, and a gate terminal of the NMOS transistor SNT1 may be connected to a line of the delayed pulse signal NPLS_D.

The NMOS transistor SNT1 may be turned on in response to the delayed pulse signal NPLS_D having the logic high level. As the NMOS transistor SNT1 is turned on, the line of the ground voltage VGND connected to the NMOS transistor INT2 may be connected to the node NPG. Accordingly, the ground voltage VGND may be provided to the node NPG.

The PMOS transistor SPT1 may be turned on in response to the delayed inverted pulse signal NPLSb_D having the logic low level. As the PMOS transistor SPT1 is turned on, the line of the positive power gating voltage VPGP connected to the PMOS transistor IPT2 may be connected to the node NPG. Accordingly, the positive power gating voltage VPGP may be provided to the node NPG.

Also, the NMOS transistor SNT1 may be turned off in response to the delayed pulse signal NPLS_D having the logic low level, and the PMOS transistor SPT1 may be turned off in response to the delayed inverted pulse signal NPLSb_D having the logic high level. Accordingly, the second inverter chain circuit 215a may be disconnected from the node NPG. Here, the short protection circuit 216a may prevent the short-circuit between the line of the positive power gating voltage VPGP connected to the positive power supply terminal of the second inverter chain circuit 215a and the line of the second power supply voltage VDD2 connected to the boosting switch 213a.

Referring to FIG. 9, the diagram shows a timing chart of the active mode ACT and the standby mode STBY. Referring to FIGS. 6 and 9, prior to a point in time t1a, the control logic circuit 121 may output the power gating enable signal PGEN having the logic low level in response to the command CMD indicating the active mode ACT. From the point in time t1a to a point in time t3a, the control logic circuit 121 may output the power gating enable signal PGEN having the logic high level in response to the command CMD indicating the standby mode STBY. After the point in time t3a, the control logic circuit 121 may output the power gating enable signal PGEN having the logic low level in response to the command CMD indicating the active mode ACT. Hereafter, the operation of the boosting control circuit 210a from the point in time t1a to the point in time t3a is described.

From the point in time t1a, the pulse generating circuit 211a may output the pulse signal NPLS having the logic low level during the pulse time t_NPLS in response to the power gating enable signal PGEN having the logic high level. After the pulse time t_NPLS, the pulse generating circuit 211a may output the pulse signal NPLS having the logic high level.

Also, from the point in time t1a, the inverter circuit 212a-2 of the first inverter chain circuit 212a may output the first power gating signal PG1a having the level of the ground voltage VGND during the pulse time t_NPLS in response to the pulse signal NPLS having the logic low level. After the pulse time t_NPLS, the inverter circuit 212a-2 of the first inverter chain circuit 212a may output the first power gating signal PG1a having the level of the positive power gating voltage VPGP in response to the pulse signal NPLS having the logic high level.

Also, from the point in time t1a, the delay circuit 214a may output the delayed pulse signal NPLS_D having the logic low level during the pulse time t_NPLS and the delay time DP in response to the pulse signal NPLS having the logic low level. From a point in time t2a after the pulse time t_NPLS and the delay time DP, the delay circuit 214a may output the delayed pulse signal NPLS_D having the logic high level.

Also, from the point in time t1a, the inverter circuit 215a-2 of the second inverter chain circuit 215a may output the second power gating signal PG2a having the level of the positive power gating voltage VPGP in response to the power gating enable signal PGEN having the logic high level.

In addition, during the pulse time t_NPLS from the point in time t1a, the PMOS transistor BPT is turned on in response to the first power gating signal PG1a having the level of the ground voltage VGND. Accordingly, the second power supply voltage VDD2 may be provided to the node NPG from the line of the second power supply voltage VDD2. After the pulse time t_NPLS, the PMOS transistor BPT is turned off in response to the first power gating signal PG1a having the level of the positive power gating voltage VPGP. Accordingly, the second power supply voltage VDD2 may not be supplied to the node NPG from the line of the second power supply voltage VDD2. Here, during the delay time DP after the pulse time t_NPLS, the node NPG may be disconnected from both the line of the second power supply voltage VDD2 and the line of the positive power gating voltage VPGP, and accordingly, a short-circuit between the line of the second power supply voltage VDD2 and the line of the positive power gating voltage VPGP may be prevented.

The second power gating signal PG2a having the level of the positive power gating voltage VPGP may be output from the point in time t1a, but not be provided to the node NPG. This is because the logic level of the delayed inverted pulse signal NPLSb_D is logic high during the pulse time t_NPLS and the delay time DP, and thus, the PMOS transistor SPT1 is not turned on.

From the point in time t2a after the pulse time t_NPLS and the delay time DP, the PMOS transistor SPT1 may be turned on in response to the delayed inverted pulse signal NPLSb_D having the logic low level. From the point in time t2a, the PMOS transistor SPT1 is turned on, and thus, the positive power gating voltage VPGP may be provided to the node NPG from the line of the positive power gating voltage VPGP.

As described above, according to the inventive concept, the voltage level of the node NPG is not raised to the positive power gating voltage VPGP at once, but is raised to the second power supply voltage VDD2 in an intermediate stage and then raised to the positive power gating voltage VPGP. This may reduce the power consumed by the power gating operation of the first power gating circuit 200.

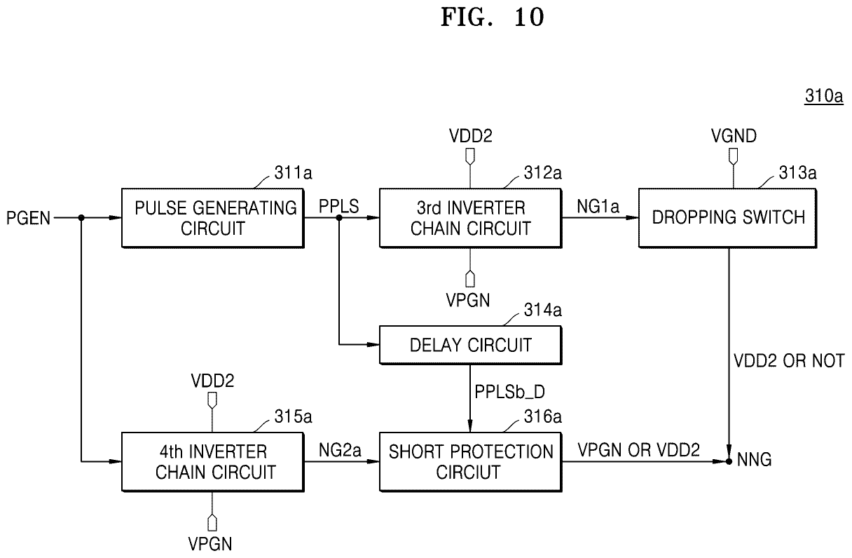

FIG. 10 is a block diagram showing an example of a dropping control circuit 310a according to the inventive concept.

Referring to FIG. 10, the dropping control circuit 310a may include a pulse generating circuit 311a, a third inverter chain circuit 312a, a dropping switch 313a, a delay circuit 314a, a fourth inverter chain circuit 315a, and a short protection circuit 316a.

The pulse generating circuit 311a may output a pulse signal PPLS in response to the power gating enable signal PGEN. For example, when the power gating enable signal PGEN transitions from the logic low level to the logic high level, the pulse generating circuit 311a may output the pulse signal PPLS having the logic high level.

Each of the third inverter chain circuit 312a and the fourth inverter chain circuit 315a may include a plurality of inverter circuits that are connected to each other in series. Here, a positive power supply terminal of each of the inverter circuits may be connected to the line of the second power supply voltage VDD2, and a negative power supply terminal of each of the inverter circuits may be connected to the line of the negative power gating voltage VPGN. The third inverter chain circuit 312a and the fourth inverter chain circuit 315a may output the second power supply voltage VDD2 or the negative power gating voltage VPGN according to a logic level of an input signal.

The third inverter chain circuit 312a may receive the pulse signal PPLS as an input signal and output the second power supply voltage VDD2 or the negative power gating voltage VPGN as a first power gating signal NG1a according to the logic level of the pulse signal PPLS.

The fourth inverter chain circuit 315a may receive the power gating enable signal PGEN as an input signal and output the second power supply voltage VDD2 or the negative power gating voltage VPGN as a second power gating signal NG2a according to the logic level of the power gating enable signal PGEN.

The dropping switch 313a may be connected between the line of the ground voltage VGND and the node NNG. The dropping switch 313a may be turned on or off in response to the first power gating signal NG1a. For example, the dropping switch 313a may be turned on in response to the first power gating signal NG1a having the level of the second power supply voltage VDD2, and accordingly, the line of the ground voltage VGND may be connected to the node NNG. Also, the dropping switch 313a may be turned off in response to the first power gating signal NG1a having the negative power gating voltage VPGN, and accordingly, the line of the ground voltage VGND may be disconnected from the node NNG.

The delay circuit 314a may receive the pulse signal PPLS as an input signal and output a delayed inverted pulse signal PPLSb_D. Here, the delayed inverted pulse signal PPLSb_D may represent a pulse signal having a form in which a period of time having a specific logic level of the inverted signal of the pulse signal PPLS has been increased by a predetermined amount of time. For example, when the pulse signal PPLS has the logic high level, the delayed inverted pulse signal PPLSb_D may represent the inverted signal of the pulse signal PPLS, and the delayed inverted pulse signal PPLSb_D may be a pulse signal having a form in which a period of time having the logic low level is increased by a predetermined amount of time.

The short protection circuit 316a may be connected between the fourth inverter chain circuit 315a and the node NNG. The short protection circuit 316a may be turned on or off in response to the delayed inverted pulse signal PPLSb_D. For example, the short protection circuit 316a may be turned on in response to the delayed inverted pulse signal PPLSb_D having the logic high level, and accordingly, the fourth inverter chain circuit 315a may be connected to the node NNG. Accordingly, the short protection circuit 316a may provide the node NNG with the second power supply voltage VDD2 or the negative power gating voltage VPGN, which represents the voltage level of the second power gating signal NG2a.

Also, the short protection circuit 316a may be turned off in response to the delayed inverted pulse signal PPLSb_D having the logic low level, and accordingly, the fourth inverter chain circuit 315a may be disconnected from the node NNG. Here, the short protection circuit 316a may prevent the short-circuit between the line of the negative power gating voltage VPGN connected to the negative power supply terminal of the fourth inverter chain circuit 315a and the line of the ground voltage VGND connected to the dropping switch 313a.

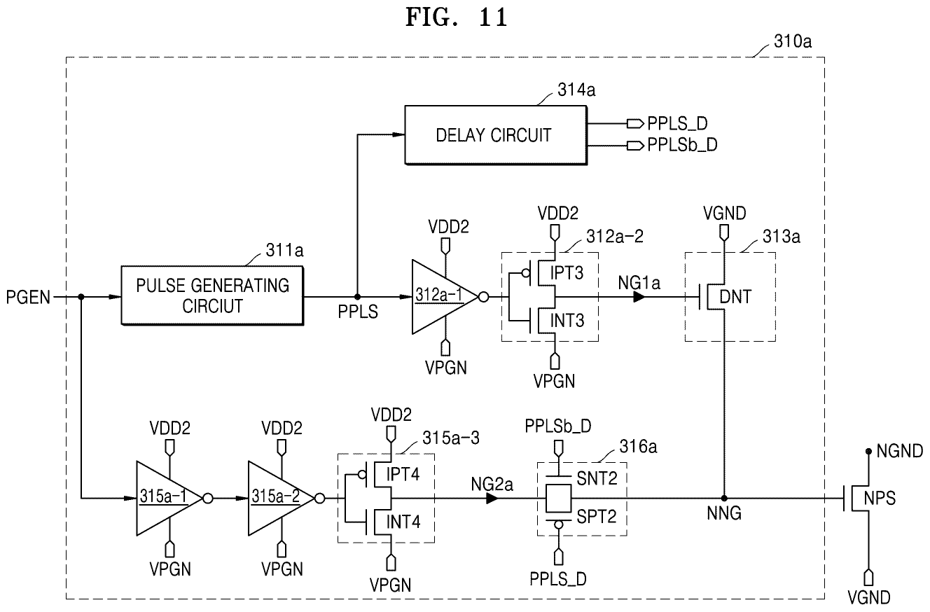

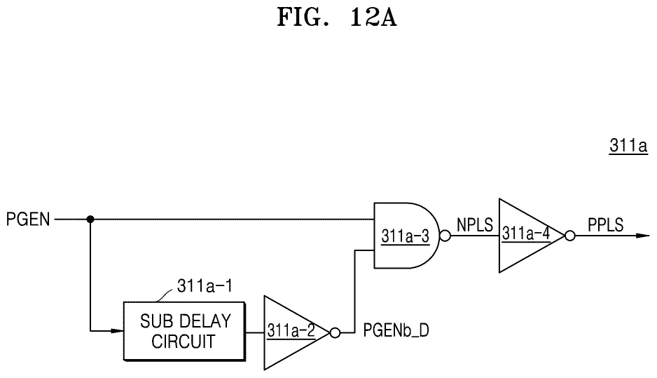

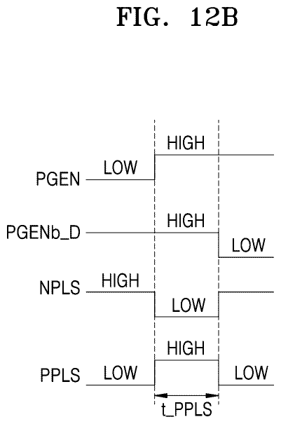

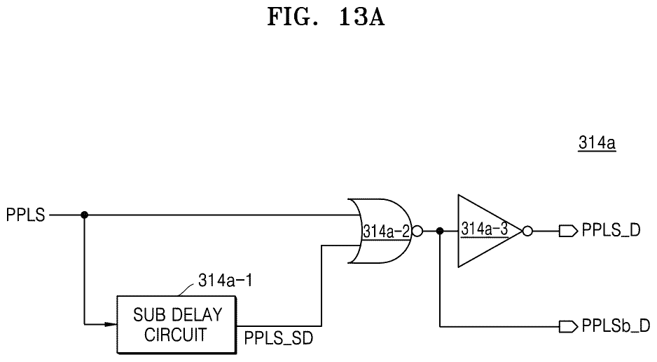

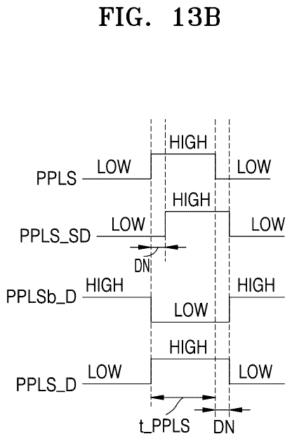

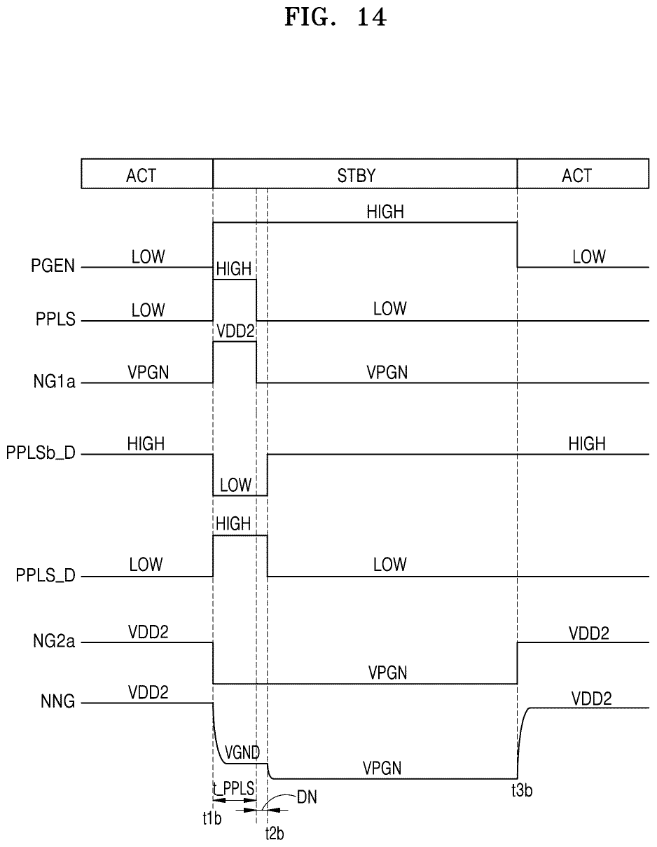

FIG. 11 is a diagram of an equivalent circuit according to an example of the dropping control circuit 310a of FIG. 10. FIG. 12A shows an equivalent circuit according to an example of the pulse generating circuit 311a of FIG. 11, and FIG. 12B is a timing chart of the equivalent circuit. FIG. 13A shows an equivalent circuit according to an example of the delay circuit 314a of FIG. 11, and FIG. 13B is a timing chart of the equivalent circuit. FIG. 14 is a timing chart of the dropping control circuit 310a of FIG. 11.

Prior to describing the dropping control circuit 310a of FIG. 11, the pulse generating circuit 311a and the delay circuit 314a are described first with reference to FIGS. 12A and 12B and FIGS. 13A and 13B.

Referring to FIG. 12A, the pulse generating circuit 311a may include a sub delay circuit 311a-1, an inverter circuit 311a-2, a NAND logic circuit 311a-3, and an inverter circuit 311a-4.

The sub delay circuit 311a-1 may receive the power gating enable signal PGEN as an input signal and output a delayed power gating enable signal. The inverter circuit 311a-2 may receive the delayed power gating enable signal as an input signal and output a delayed inverted power gating enable signal PGENb_D. The NAND logic circuit 311a-3 may receive the power gating enable signal PGEN and the delayed inverted power gating enable signal PGENb_D as input signals and output the pulse signal NPLS. The inverter circuit 311a-4 may receive the pulse signal NPLS as an input signal and output the pulse signal PPLS by inverting the pulse signal NPLS.

Here, the sub delay circuit 311a-1 may output, as an output signal, a signal having a form in which the input signal is delayed by a predetermined pulse time t_PPLS. The pulse time t_PPLS may be determined in advance by considering a response speed or power consumption, etc., according to characteristics of current in total circuits. Also, the sub delay circuit 311a-1 may be formed as an inverter chain circuit, etc., and the pulse time t_PPLS may be determined according to design parameters (e.g., the number of steps in the inverter chain, etc.).

Referring to FIG. 12B, when the power gating enable signal PGEN is continuously at a low level, the logic levels of both the delayed inverted power gating enable signal PGENb_D and the pulse signal NPLS may also be at the logic high level. When the power gating enable signal PGEN transitions from the logic low level to the logic high level, the delayed inverted power gating enable signal PGENb_D may transition from the logic high level to the logic low level after a pulse time t_PPLS has elapsed. Accordingly, the pulse signal NPLS may have the logic low level during the pulse time t_PPLS. Since the pulse signal NPLS has the logic low level during the pulse time t_PPLS, the pulse signal PPLS, which is the inverted signal of the pulse signal NPLS, may have the logic high level during the pulse time t_PPLS.

Referring to FIG. 13A, the delay circuit 314a may include a sub delay circuit 314a-1, a NOR logic circuit 314a-2, and an inverter circuit 314a-3.

The sub delay circuit 314a-1 may receive the pulse signal PPLS of FIG. 12A as an input signal and output a pulse signal PPLS_SD having a form in which all of the pulse signal PPLS is delayed by a delay time DN. The NOR logic circuit 314a-2 may receive the pulse signal PPLS and the delayed pulse signal PPLS_SD as input signals and output a delayed inverted pulse signal PPLSb_D. The inverter circuit 314a-3 may receive the delayed inverted pulse signal PPLSb_D as an input signal and output a delayed pulse signal PPLS_D.

Here, the sub delay circuit 314a-1 may output, as an output signal, a signal having a form in which the input signal is delayed by a predetermined delay time DN. The delay time DN may be determined in advance by considering a response speed or power consumption, etc., according to characteristics of current in total circuits. Also, the sub delay circuit 314a-1 may be formed as an inverter chain circuit, etc., and the pulse time t_PPLS may be determined according to design parameters (e.g., the number of steps in the inverter chain, etc.).

Referring to FIG. 13B, here, the delayed inverted pulse signal PPLSb_D may represent an inverted signal of a pulse signal having a form in which a period of time having a specific logic level of the pulse signal PPLS has been increased by the predetermined delay time DN. When the pulse signal PPLS has a logic high level, the delayed inverted pulse signal PPLSb_D may represent the inverted signal of the pulse signal having a form in which a period of time having the logic high level of the pulse signal PPLS has been increased by the predetermined delay time DN.

Returning to FIG. 11, the dropping control circuit 310a of FIG. 11 is described with reference to FIGS. 11 and 14.

The third inverter chain circuit 312a may include two inverter circuits, and the fourth inverter chain circuit 315a may include three inverter circuits. However, the embodiment is not limited thereto, and the number of inverter circuits in the third and fourth inverter chain circuits 312a and 315a may vary according to embodiments. The number of inverter circuits may be determined by considering a response speed or power consumption, etc., according to characteristics of current in total circuits. Also, the inverter circuit may be formed as the CMOS transistor and configured such that the NMOS transistor and the PMOS transistor in the inverter circuit operate in a complementary manner.

Referring to FIG. 11, the third inverter chain circuit 312a may include an inverter circuit 312a-1 and an inverter circuit 312a-2. The inverter circuit 312a-1 and the inverter circuit 312a-2 may be connected to each other in series. The inverter circuit 312a-1 may receive the pulse signal PPLS as an input signal, and the inverter circuit 312a-2 may output the second power supply voltage VDD2 or the negative power gating voltage VPGN as a first power gating signal NG1a according to the logic level of the pulse signal PPLS.

Referring to FIG. 11, the inverter circuit 312a-2 may include a PMOS transistor IPT3 and an NMOS transistor INT3. A source terminal of the PMOS transistor IPT3 may be connected to the line of the second power supply voltage VDD2, a drain terminal of the PMOS transistor IPT3 may be connected to a gate terminal of an NMOS transistor DNT and a drain terminal of the NMOS transistor INT3, and a gate terminal of the PMOS transistor IPT3 may be connected to an output terminal of the inverter circuit 312a-1. A source terminal of the NMOS transistor INT3 may be connected to the line of the negative power gating voltage VPGN, the drain terminal of the NMOS transistor INT3 may be connected to the gate terminal of the NMOS transistor DNT and the drain terminal of the PMOS transistor IPT3, and a gate terminal of the NMOS transistor INT3 may be connected to the output terminal of the inverter circuit 312a-1.

Referring to FIG. 11, the fourth inverter chain circuit 315a may include an inverter circuit 315a-1, an inverter circuit 315a-2, and an inverter circuit 315a-3. The inverter circuit 315a-1, the inverter circuit 315a-2, and the inverter circuit 315a-3 may be connected to each other in series. The inverter circuit 315a-1 may receive the power gating enable signal PGEN as an input signal, and the inverter circuit 315a-3 may output the second power supply voltage VDD2 or the negative power gating voltage VPGN as a second power gating signal NG2a according to the logic level of the power gating enable signal PGEN.

Referring to FIG. 11, the inverter circuit 315a-3 may include a PMOS transistor IPT4 and an NMOS transistor INT4. A source terminal of the PMOS transistor IPT4 may be connected to the line of the second power supply voltage VDD2, a drain terminal of the PMOS transistor IPT4 may be connected to the short protection circuit 316a and a drain terminal of the NMOS transistor INT4, and a gate terminal of the PMOS transistor IPT4 may be connected to an output terminal of the inverter circuit 315a-2. A source terminal of the NMOS transistor INT4 may be connected to the line of the negative power gating voltage VPGN, the drain terminal of the NMOS transistor INT4 may be connected to the short protection circuit 316a and the drain terminal of the PMOS transistor IPT4, and a gate terminal of the NMOS transistor INT4 may be connected to the output terminal of the inverter circuit 315a-2.

Referring to FIG. 11, the dropping switch 313a may include the NMOS transistor DNT. The dropping switch 313a may be connected between the line of the ground voltage VGND and the node NNG. The NMOS transistor DNT may be turned on or off in response to the first power gating signal NG1a. For example, the NMOS transistor DNT may be turned on in response to the first power gating signal NG1a having the level of the second power supply voltage VDD2, and accordingly, the line of the ground voltage VGND may be connected to the node NNG. Also, the NMOS transistor DNT may be turned off in response to the first power gating signal NG1a having the level of the negative power gating voltage VPGN, and accordingly, the line of the ground voltage VGND may be disconnected from the node NNG.

Referring to FIG. 11, the short protection circuit 316a may include an NMOS transistor SNT2 and a PMOS transistor SPT2. A source terminal of the PMOS transistor SPT2 may be connected to an output terminal of the inverter circuit 315a-3 and a source terminal of the NMOS transistor SNT2, a drain terminal of the PMOS transistor SPT2 may be connected to the node NNG, and a gate terminal of the PMOS transistor SPT2 may be connected to a line of the delayed pulse signal PPLS_D. The source terminal of the NMOS transistor SNT2 may be connected to the output terminal of the inverter circuit 315a-3 and the source terminal of the PMOS transistor SPT2, a drain terminal of the NMOS transistor SNT2 may be connected to the node NNG, and a gate terminal of the NMOS transistor SNT2 may be connected to the line of the delayed inverted pulse signal PPLSb_D.

The NMOS transistor SNT2 may be turned on in response to the delayed inverted pulse signal PPLSb_D having the logic high level. As the NMOS transistor SNT2 is turned on, the line of the negative power gating voltage VPGN connected to the NMOS transistor INT4 may be connected to the node NNG. Accordingly, the negative power gating voltage VPGN may be provided to the node NNG.

The PMOS transistor SPT2 may be turned on in response to the delayed pulse signal PPLS_D having the logic low level. As the PMOS transistor SPT2 is turned on, the line of the second power supply voltage VDD2 connected to the PMOS transistor IPT4 may be connected to the node NNG. Accordingly, the second power supply voltage VDD2 may be provided to the node NNG.

Also, the NMOS transistor SNT2 may be turned off in response to the delayed inverted pulse signal PPLSb_D having the logic low level, and the PMOS transistor SPT2 may be turned off in response to the delayed pulse signal PPLS_D having the logic high level. Accordingly, the fourth inverter chain circuit 315a may be disconnected from the node NNG. Here, the short protection circuit 316a may prevent the short-circuit between the line of the negative power gating voltage VPGN connected to the negative power supply terminal of the fourth inverter chain circuit 315a and the line of the ground voltage VGND connected to the dropping switch 313a.

Referring to FIG. 14, the diagram shows a timing chart of the active mode ACT and the standby mode STBY. Referring to FIGS. 11 and 14, prior to a point in time t1b, the control logic circuit 121 may output the power gating enable signal PGEN having the logic low level in response to the command CMD indicating the active mode ACT. From the point in time t1b to a point in time t3b, the control logic circuit 121 may output the power gating enable signal PGEN having the logic high level in response to the command CMD indicating the standby mode STBY. After the point in time t3b, the control logic circuit 121 may output the power gating enable signal PGEN having the logic low level in response to the command CMD indicating the active mode ACT. Hereafter, the operation of the dropping control circuit 310a from the point in time t1b to the point in time t3b is described.

From the point in time t1b, the pulse generating circuit 311a may output the pulse signal PPLS having the logic high level during the pulse time t_PPLS in response to the power gating enable signal PGEN having the logic high level. After the pulse time t_PPLS, the pulse generating circuit 311a may output the pulse signal PPLS having the logic low level.

Also, from the point in time t1b, the inverter circuit 312a-2 of the third inverter chain circuit 312a may output the first power gating signal NG1a having the level of the second power supply voltage VDD2 during the pulse time t_PPLS in response to the pulse signal PPLS having the logic high level. After the pulse time t_PPLS, the inverter circuit 312a-2 of the third inverter chain circuit 312a may output the first power gating signal NG1a having the level of the negative power gating voltage VPGN in response to the pulse signal PPLS having the logic low level.

Also, from the point in time t1b, the delay circuit 314a may output the delayed inverted pulse signal PPLSb_D having the logic low level during the pulse time t_PPLS and the delay time DN in response to the pulse signal PPLS having the logic high level. From a point in time t2b after the pulse time t_PPLS and the delay time DN, the delay circuit 314a may output the delayed inverted pulse signal PPLSb_D having the logic high level.

Also, from the point in time t1b, the inverter circuit 315a-3 of the fourth inverter chain circuit 315a may output the second power gating signal NG2a having the level of the negative power gating voltage VPGN in response to the power gating enable signal PGEN having the logic high level.

In addition, during the pulse time t_PPLS from the point in time t1b, the NMOS transistor DNT is turned on in response to the first power gating signal NG1a having the level of the second power supply voltage VDD2. Accordingly, the ground voltage VGND may be provided to the node NNG from the line of the ground voltage VGND. After the pulse time t_PPLS, the NMOS transistor DNT is turned off in response to the first power gating signal NG1a having the level of the negative power gating voltage VPGN. Accordingly, the ground voltage VGND may not be supplied to the node NNG from the line of the ground voltage VGND. Here, during the delay time DN after the pulse time t_PPLS, the node NNG may be disconnected from both the line of the ground voltage VGND and the line of the negative power gating voltage VPGN, and accordingly, a short-circuit between the line of the ground voltage VGND and the line of the negative power gating voltage VPGN may be prevented.

The second power gating signal NG2a having the level of the negative power gating voltage VPGN may be output from the point in time t1b, but not be provided to the node NNG. This is because the logic level of the delayed pulse signal PPLS_D is logic high during the pulse time t_PPLS and the delay time DN, and thus, the PMOS transistor SPT2 is not turned on.

From the point in time t2b after the pulse time t_PPLS and the delay time DN, the PMOS transistor SPT2 may be turned on in response to the delayed pulse signal PPLS_D having the logic low level. From the point in time t2b, the PMOS transistor SPT2 is turned on, and thus, the negative power gating voltage VPGN may be provided to the node NNG from the line of the negative power gating voltage VPGN.

As described above, according to the inventive concept, the voltage level of the node NNG is not lowered to the negative power gating voltage VPGN at once, but is lowered to the ground voltage VGND in an intermediate stage and then lowered to the negative power gating voltage VPGN. This may reduce the power consumed by the power gating operation of the second power gating circuit 300.

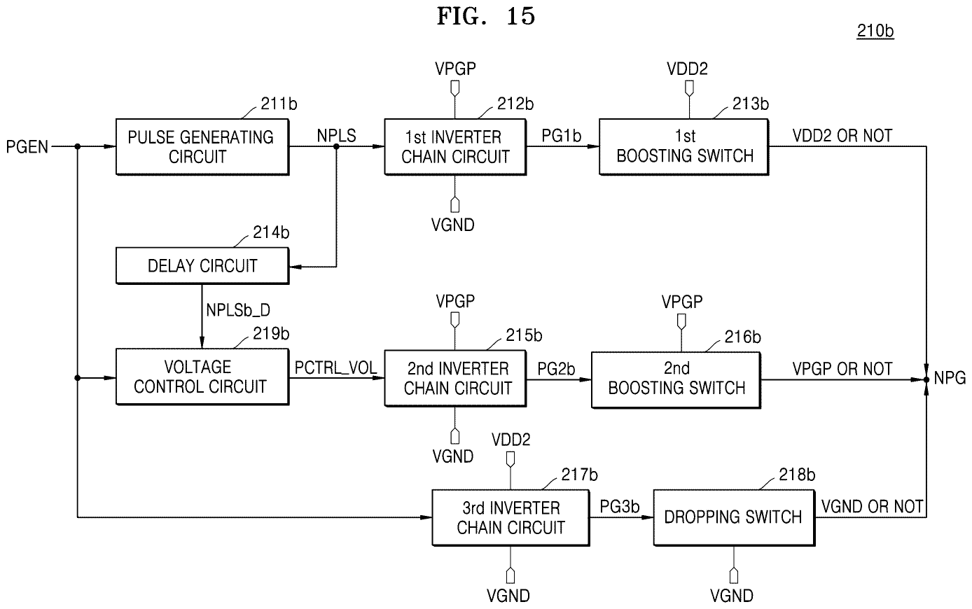

FIG. 15 is a block diagram showing another example of a boosting control circuit 210b according to the inventive concept.

Referring to FIG. 15, the boosting control circuit 210b may include a pulse generating circuit 211b, a first inverter chain circuit 212b, a first boosting switch 213b, a delay circuit 214b, a second inverter chain circuit 215b, a second boosting switch 216b, a third inverter chain circuit 217b, a dropping switch 218b, and a voltage control circuit 219b.

The pulse generating circuit 211b may output the pulse signal NPLS in response to the power gating enable signal PGEN. For example, when the power gating enable signal PGEN transitions from the logic low level to the logic high level, the pulse generating circuit 211b may output the pulse signal NPLS having the logic low level.

Each of the first inverter chain circuit 212b, the second inverter chain circuit 215b, and the third inverter chain circuit 217b may include a plurality of inverter circuits connected to each other in series.

Here, a positive power supply terminal of each of inverter circuits of the first inverter chain circuit 212b and the second inverter chain circuit 215b may be connected to the line of the positive power gating voltage VPGP, and a negative power supply terminal of each of the inverter circuits of the first inverter chain circuit 212b and the second inverter chain circuit 215b may be connected to the line of the ground voltage VGND. The first inverter chain circuit 212b and the second inverter chain circuit 215b may output the positive power gating voltage VPGP or the ground voltage VGND according to a logic level of an input signal. A positive power supply terminal of each of inverter circuits of the third inverter chain circuit 217b may be connected to the line of the second power supply voltage VDD2, and a negative power supply terminal of each of the inverter circuits of the third inverter chain circuit 217b may be connected to the line of the ground voltage VGND. The third inverter chain circuit 217b may output the second power supply voltage VDD2 or the ground voltage VGND according to a logic level of an input signal.

In some embodiments, unlike that shown in FIG. 15, the positive power supply terminal of each of the inverter circuits of the third inverter chain circuit 217b may be connected to the line of the positive power gating voltage VPGP.

The first inverter chain circuit 212b may receive the pulse signal NPLS as an input signal and output the positive power gating voltage VPGP or the ground voltage VGND as a first power gating signal PG1b according to the logic level of the pulse signal NPLS.

The second inverter chain circuit 215b may receive a voltage control signal PCTRL_VOL as an input signal and output the positive power gating voltage VPGP or the ground voltage VGND as a second power gating signal PG2b according to the logic level of the voltage control signal PCTRL_VOL.

The third inverter chain circuit 217b may receive the power gating enable signal PGEN as an input signal and output the second power supply voltage VDD2 or the ground voltage VGND as a third power gating signal PG3b according to the logic level of the power gating enable signal PGEN.

The first boosting switch 213b may be connected between the line of the second power supply voltage VDD2 and the node NPG. The first boosting switch 213b may be turned on or off in response to the first power gating signal PG1b. For example, the first boosting switch 213b may be turned on in response to the first power gating signal PG1b having the level of the ground voltage VGND, and accordingly, the line of the second power supply voltage VDD2 may be connected to the node NPG. Also, the first boosting switch 213b may be turned off in response to the first power gating signal PG1b having the level of the positive power gating voltage VPGP, and accordingly, the line of the second power supply voltage VDD2 may be disconnected from the node NPG.

The second boosting switch 216b may be connected between the line of the positive power gating voltage VPGP and the node NPG. The second boosting switch 216b may be turned on or off in response to the second power gating signal PG2b. For example, the second boosting switch 216b may be turned on in response to the second power gating signal PG2b having the level of the ground voltage VGND, and accordingly, the line of the positive power gating voltage VPGP may be connected to the node NPG. Also, the second boosting switch 216b may be turned off in response to the second power gating signal PG2b having the level of the positive power gating voltage VPGP, and accordingly, the line of the positive power gating voltage VPGP may be disconnected from the node NPG.

The dropping switch 218b may be connected between the line of the ground voltage VGND and the node NPG. The dropping switch 218b may be turned on or off in response to the third power gating signal PG3b. For example, the dropping switch 218b may be turned on in response to the third power gating signal PG3b having the level of the second power supply voltage VDD2, and accordingly, the line of the ground voltage VGND may be connected to the node NPG. Also, the dropping switch 218b may be turned off in response to the third power gating signal PG3b having the level of the ground voltage VGND, and accordingly, the line of the ground voltage VGND may be disconnected from the node NPG.

The delay circuit 214b may receive the pulse signal NPLS as an input signal and output the delayed inverted pulse signal NPLSb_D. Here, the delayed inverted pulse signal NPLSb_D may represent a pulse signal having a form in which a period of time having a specific logic level of the inverted signal of the pulse signal NPLS has been increased by a predetermined amount of time. For example, when the pulse signal NPLS has the logic low level, the delayed inverted pulse signal NPLSb_D may represent the inverted signal of the pulse signal NPLS, and the delayed inverted pulse signal NPLSb_D may be a pulse signal having a form in which a period of time having the logic high level is increased by a predetermined amount of time.

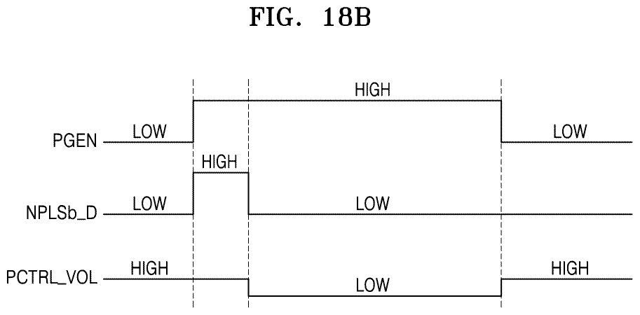

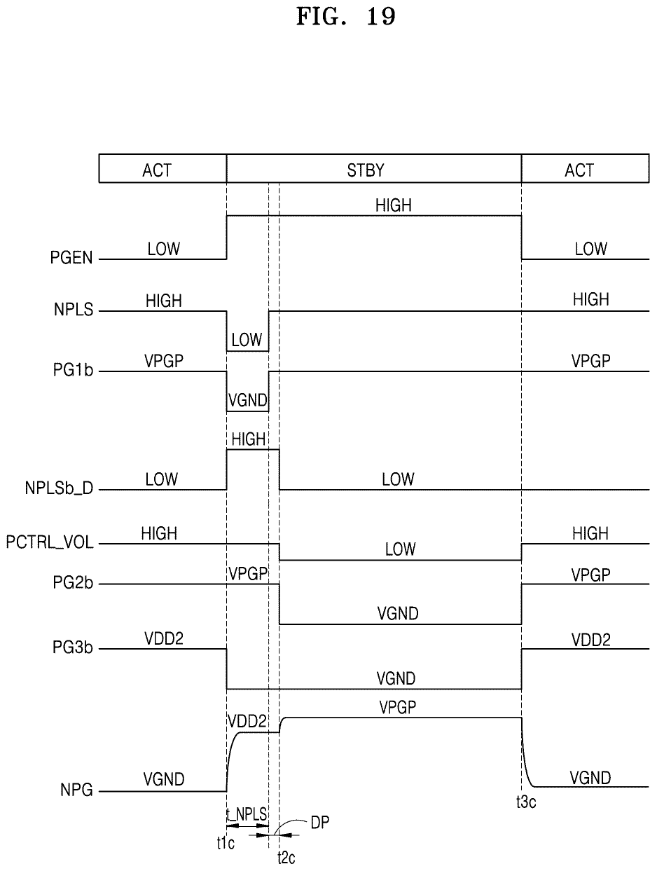

The voltage control circuit 219b may receive the power gating enable signal PGEN and the delayed inverted pulse signal NPLSb_D as input signals and may output the voltage control signal PCTRL_VOL. The voltage control signal PCTRL_VOL of the voltage control circuit 219b is described in detail with reference to FIG. 19.

Compared to the boosting control circuit 210a of FIG. 5, the boosting control circuit 210b of FIG. 15 may not include the short protection circuit 216a. Instead, the boosting control circuit 210b may include two voltage boosting paths for raising the voltage of the node NPG and one voltage dropping path for lowering the voltage of the node NPG, thereby preventing a short-circuit between voltage lines.

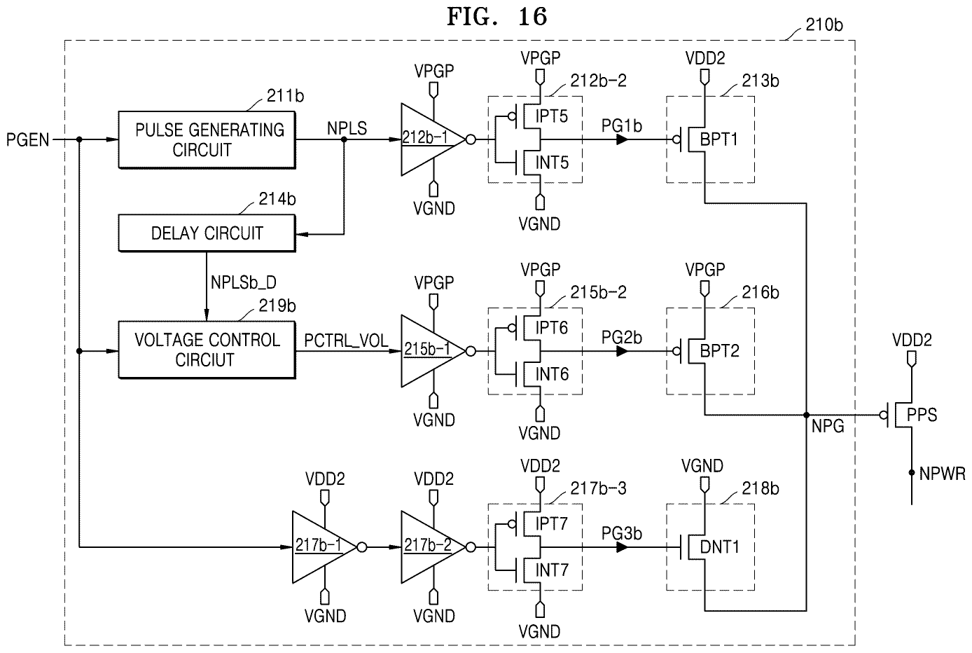

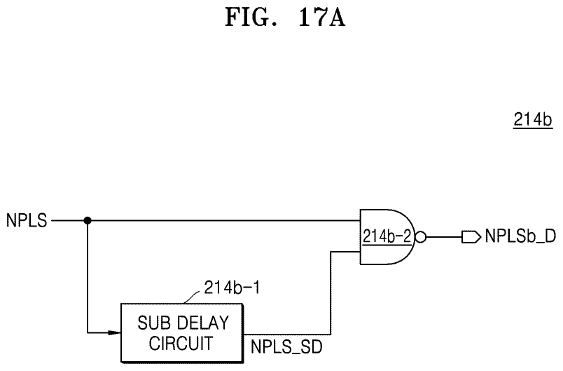

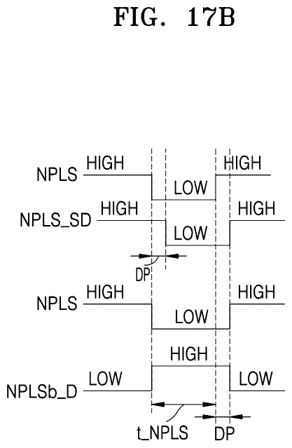

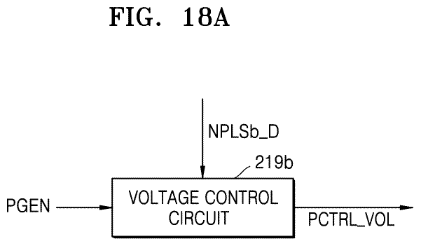

FIG. 16 is a diagram showing an equivalent circuit according to an example of the boosting control circuit 210b of FIG. 15. FIG. 17A shows an equivalent circuit according to an example of the delay circuit 214b of FIG. 16, and FIG. 17B is a timing chart of the equivalent circuit. FIGS. 18A and 18B are diagrams illustrating the voltage control circuit 219b of FIG. 16. FIG. 19 is a timing chart of the boosting control circuit 210b of FIG. 16.

The pulse generating circuit 211b of FIGS. 15 and 16 may correspond to the pulse generating circuit 211a of FIG. 7, and repeated descriptions thereof are omitted.

Prior to describing the boosting control circuit 210b of FIG. 16, the delay circuit 214b and the voltage control circuit 219b are described first with reference to FIGS. 17A and 17B and FIGS. 18A and 18B.

Referring to FIG. 17A, the delay circuit 214b may include a sub delay circuit 214b-1 and a NAND logic circuit 214b-2. The sub delay circuit 214b-1 and the NAND logic circuit 214b-2 may correspond to the sub delay circuit 214a-1 and the NAND logic circuit 214a-2 of FIG. 8, respectively, and repeated descriptions thereof are omitted. Compared to the delay circuit 214a of FIG. 8, the delay circuit 214b may not include the inverter circuit 214a-3.

Referring to FIG. 17B, the delay circuit 214b may receive the pulse signal NPLS as an input signal and output the delayed inverted pulse signal NPLSb_D. Here, the delayed inverted pulse signal NPLSb_D may represent an inverted signal of a pulse signal having a form in which a period of time having a specific logic level of the pulse signal NPLS has been increased by the predetermined delay time DP. When the pulse signal NPLS has a logic low level, the delayed inverted pulse signal NPLSb_D may represent the inverted signal of the pulse signal having a form in which a period of time having the logic low level of the pulse signal NPLS has been increased by the predetermined delay time DP.

Referring to FIG. 18A, the voltage control circuit 219b may receive the power gating enable signal PGEN and the delayed inverted pulse signal NPLSb_D as input signals and may output the voltage control signal PCTRL_VOL.

Referring to FIG. 18B, when the logic level of the power gating enable signal PGEN is logic low, the voltage control circuit 219b may output the voltage control signal PCTRL_VOL having the logic high level, irrespective of the logic level of the delayed inverted pulse signal NPLSb_D.

Referring to FIG. 18B, when the logic level of the power gating enable signal PGEN is logic high, the voltage control circuit 219b may output the voltage control signal PCTRL_VOL, based on the logic level of the delayed inverted pulse signal NPLSb_D. When the logic level of the power gating enable signal PGEN is logic high and the logic level of the delayed inverted pulse signal NPLSb_D is logic high, the voltage control circuit 219b may output the voltage control signal PCTRL_VOL having the logic high level. When the logic level of the power gating enable signal PGEN is logic high and the logic level of the delayed inverted pulse signal NPLSb_D is logic low, the voltage control circuit 219b may output the voltage control signal PCTRL_VOL having the logic low level.

Returning to FIG. 16, the boosting control circuit 210b of FIG. 16 is described with reference to FIGS. 16 and 19.

Referring to FIG. 16, each of the first inverter chain circuit 212b and the second inverter chain circuit 215b may include two inverter circuits. The third inverter chain circuit 217b may include three inverter circuits. However, the embodiment is not limited thereto, and the number of inverter circuits in the first to third inverter chain circuits 212b, 215b, and 217b may vary according to embodiments. The number of inverter circuits may be determined by considering a response speed or power consumption, etc., according to characteristics of current in total circuits. Also, the inverter circuit may be formed as the CMOS transistor and configured such that the NMOS transistor and the PMOS transistor in the inverter circuit operate in a complementary manner.

Referring to FIG. 16, the first inverter chain circuit 212b may include an inverter circuit 212b-1 and an inverter circuit 212b-2. The inverter circuit 212b-1 and the inverter circuit 212b-2 may be connected to each other in series. The inverter circuit 212b-1 may receive the pulse signal NPLS as an input signal, and the inverter circuit 212b-2 may output the positive power gating voltage VPGP or the ground voltage VGND as the first power gating signal PG1b according to the logic level of the pulse signal NPLS.

Referring to FIG. 16, the inverter circuit 212b-2 may include a PMOS transistor IPT5 and an NMOS transistor INT5. A source terminal of the PMOS transistor IPT5 may be connected to the line of the positive power gating voltage VPGP, a drain terminal of the PMOS transistor IPT5 may be connected to a gate terminal of a PMOS transistor BPT1 and a drain terminal of the NMOS transistor INT5, and a gate terminal of the PMOS transistor IPT5 may be connected to an output terminal of the inverter circuit 212b-1. A source terminal of the NMOS transistor INT5 may be connected to the line of the ground voltage VGND, the drain terminal of the NMOS transistor INT5 may be connected to the gate terminal of the PMOS transistor BPT1 and the drain terminal of the PMOS transistor IPT5, and a gate terminal of the NMOS transistor INT5 may be connected to the output terminal of the inverter circuit 212b-1.

Referring to FIG. 16, the second inverter chain circuit 215b may include an inverter circuit 215b-1 and an inverter circuit 215b-2. The inverter circuit 215b-1 and the inverter circuit 215b-2 may be connected to each other in series. The inverter circuit 215b-1 may receive the voltage control signal PCTRL_VOL as an input signal, and the inverter circuit 215b-2 may output the positive power gating voltage VPGP or the ground voltage VGND as the second power gating signal PG2b according to the logic level of the voltage control signal PCTRL_VOL.

Referring to FIG. 16, the inverter circuit 215b-2 may include a PMOS transistor IPT6 and an NMOS transistor INT6. A source terminal of the PMOS transistor IPT6 may be connected to the line of the positive power gating voltage VPGP, a drain terminal of the PMOS transistor IPT6 may be connected to a gate terminal of a PMOS transistor BPT2 and a drain terminal of the NMOS transistor INT6, and a gate terminal of the PMOS transistor IPT6 may be connected to an output terminal of the inverter circuit 215b-1. A source terminal of the NMOS transistor INT6 may be connected to the line of the ground voltage VGND, the drain terminal of the NMOS transistor INT6 may be connected to the gate terminal of the PMOS transistor BPT2 and the drain terminal of the PMOS transistor IPT6, and a gate terminal of the NMOS transistor INT6 may be connected to the output terminal of the inverter circuit 215b-1.

Referring to FIG. 16, the third inverter chain circuit 217b may include an inverter circuit 217b-1, an inverter circuit 217b-2, and an inverter circuit 217b-3. The inverter circuit 217b-1, the inverter circuit 217b-2, and the inverter circuit 217b-3 may be connected to each other in series. The inverter circuit 217b-1 may receive the power gating enable signal PGEN as an input signal, and the inverter circuit 217b-3 may output the second power supply voltage VDD2 or the ground voltage VGND as the third power gating signal PG3b according to the logic level of the power gating enable signal PGEN.

Referring to FIG. 16, the inverter circuit 217b-3 may include a PMOS transistor IPT7 and an NMOS transistor INT7. A source terminal of the PMOS transistor IPT7 may be connected to the line of the second power supply voltage VDD2, a drain terminal of the PMOS transistor IPT7 may be connected to a gate terminal of an NMOS transistor DNT1 and a drain terminal of the NMOS transistor INT7, and a gate terminal of the PMOS transistor IPT7 may be connected to an output terminal of the inverter circuit 217b-2. A source terminal of the NMOS transistor INT7 may be connected to the line of the ground voltage VGND, the drain terminal of the NMOS transistor INT7 may be connected to the gate terminal of the NMOS transistor DNT1 and the drain terminal of the PMOS transistor IPT7, and a gate terminal of the NMOS transistor INT7 may be connected to the output terminal of the inverter circuit 217b-2.

Referring to FIG. 16, the first boosting switch 213b may include the PMOS transistor BPT1. The PMOS transistor BPT1 may be connected between the line of the second power supply voltage VDD2 and the node NPG. The PMOS transistor BPT1 may be turned on or off in response to the first power gating signal PG1b. For example, the PMOS transistor BPT1 may be turned on in response to the first power gating signal PG1b having the level of the ground voltage VGND, and accordingly, the line of the second power supply voltage VDD2 may be connected to the node NPG. Also, the PMOS transistor BPT1 may be turned off in response to the first power gating signal PG1b having the level of the positive power gating voltage VPGP, and accordingly, the line of the second power supply voltage VDD2 may be disconnected from the node NPG.

Referring to FIG. 16, the second boosting switch 216b may include the PMOS transistor BPT2. The PMOS transistor BPT2 may be connected between the line of the positive power gating voltage VPGP and the node NPG. The PMOS transistor BPT2 may be turned on or off in response to the second power gating signal PG2b. For example, the PMOS transistor BPT2 may be turned on in response to the second power gating signal PG2b having the level of the ground voltage VGND, and accordingly, the line of the positive power gating voltage VPGP may be connected to the node NPG. Also, the PMOS transistor BPT2 may be turned off in response to the second power gating signal PG2b having the level of the positive power gating voltage VPGP, and accordingly, the line of the positive power gating voltage VPGP may be disconnected from the node NPG.

Referring to FIG. 16, the dropping switch 218b may include the NMOS transistor DNT1. The NMOS transistor DNT1 may be connected between the line of the ground voltage VGND and the node NPG. The NMOS transistor DNT1 may be turned on or off in response to the third power gating signal PG3b. For example, the NMOS transistor DNT1 may be turned on in response to the third power gating signal PG3b having the level of the second power source voltage VDD2, and accordingly, the line of the ground voltage VGND may be connected to the node NPG. Also, the NMOS transistor DNT1 may be turned off in response to the third power gating signal PG3b having the level of the ground voltage VGND, and accordingly, the line of the ground voltage VGND may be disconnected from the node NPG.

Referring to FIG. 19, the diagram shows a timing chart of the active mode ACT and the standby mode STBY. Referring to FIGS. 16 and 19, prior to a point in time t1c, the control logic circuit 121 may output the power gating enable signal PGEN having the logic low level in response to the command CMD indicating the active mode ACT. From the point in time t1c to a point in time t3c, the control logic circuit 121 may output the power gating enable signal PGEN having the logic high level in response to the command CMD indicating the standby mode STBY. After the point in time t3c, the control logic circuit 121 may output the power gating enable signal PGEN having the logic low level in response to the command CMD indicating the active mode ACT. Hereafter, the operation of the boosting control circuit 210b from the point in time t1c to the point in time t3c is described.

From the point in time t1c, the pulse generating circuit 211b may output the pulse signal NPLS having the logic low level during the pulse time t_NPLS in response to the power gating enable signal PGEN having the logic high level. After the pulse time t_NPLS, the pulse generating circuit 211b may output the pulse signal NPLS having the logic high level.

Also, from the point in time t1c, the inverter circuit 212b-2 of the first inverter chain circuit 212b may output the first power gating signal PG1b having the level of the ground voltage VGND during the pulse time t_NPLS in response to the pulse signal NPLS having the logic low level. After the pulse time t_NPLS, the inverter circuit 212b-2 of the first inverter chain circuit 212b may output the first power gating signal PG1b having the level of the positive power gating voltage VPGP in response to the pulse signal NPLS having the logic high level.

Also, from the point in time t1c, the delay circuit 214b may output the delayed inverted pulse signal NPLSb_D having the logic high level during the pulse time t_NPLS and the delay time DP in response to the pulse signal NPLS having the logic low level. From a point in time t2c after the pulse time t_NPLS and the delay time DP, the delay circuit 214b may output the delayed inverted pulse signal NPLSb_D having the logic low level.

Also, from the point in time t1c to the point in time t2c, the logic level of the power gating enable signal PGEN is logic high, and the logic level of the delayed inverted pulse signal NPLSb_D is logic high, as described with reference to FIG. 18. Therefore, the voltage control circuit 219b may output the voltage control signal PCTRL_VOL having the logic high level. Also, after the point in time t2c, the logic level of the power gating enable signal PGEN is logic high, and the logic level of the delayed inverted pulse signal NPLSb_D is logic low, as described with reference to FIG. 18. Therefore, the voltage control circuit 219b may output the voltage control signal PCTRL_VOL having the logic low level.

Also, from the point in time t1c to the point in time t2c, the inverter circuit 215b-2 of the second inverter chain circuit 215b may output the second power gating signal PG2b having the level of the positive power gating voltage VPGP in response to the voltage control signal PCTRL_VOL having the logic high level. Also, after the point in time t2c, the inverter circuit 215b-2 of the second inverter chain circuit 215b may output the second power gating signal PG2b having the level of the ground voltage VGND in response to the voltage control signal PCTRL_VOL having the logic low level.

Also, from the point in time t1c, the inverter circuit 217b-3 of the third inverter chain circuit 217b may output the third power gating signal PG3b having the level of the ground voltage VGND in response to the power gating enable signal PGEN having the logic high level.

In addition, during the pulse time t_NPLS from the point in time t1c, the PMOS transistor BPT1 is turned on in response to the first power gating signal PG1b having the level of the ground voltage VGND. Accordingly, the second power supply voltage VDD2 may be provided to the node NPG from the line of the second power supply voltage VDD2.

After the pulse time t_NPLS, the PMOS transistor BPT1 is turned off in response to the first power gating signal PG1b having the level of the positive power gating voltage VPGP. Accordingly, the second power supply voltage VDD2 may not be supplied to the node NPG from the line of the second power supply voltage VDD2. Here, during the delay time DP after the pulse time t_NPLS, the node NPG may be disconnected from all of the line of the second power supply voltage VDD2, the line of the positive power gating voltage VPGP, and the line of the ground voltage VGND, and accordingly, a short-circuit between the line of the second power supply voltage VDD2, the line of the positive power gating voltage VPGP, and the line of the ground voltage VGND may be prevented.

From the point in time t2c after the pulse time t_NPLS and the delay time DP, the PMOS transistor BPT2 is turned on in response to the second power gating signal PG2b having the level of the ground voltage VGND. Accordingly, the positive power gating voltage VPGP may be provided to the node NPG from the line of the positive power gating voltage VPGP.

When the command CMD indicates the active mode ACT, the dropping switch 218b is turned on in response to the third power gating signal PG3b having the level of the second power supply voltage VDD2. Accordingly, the line of the ground voltage VGND may be connected to the node NPG.

As described above, according to the inventive concept, the voltage level of the node NPG is not raised to the positive power gating voltage VPGP at once, but is raised to the second power supply voltage VDD2 in an intermediate stage and then raised to the positive power gating voltage VPGP. This may reduce the power consumed by the power gating operation of the first power gating circuit 200.

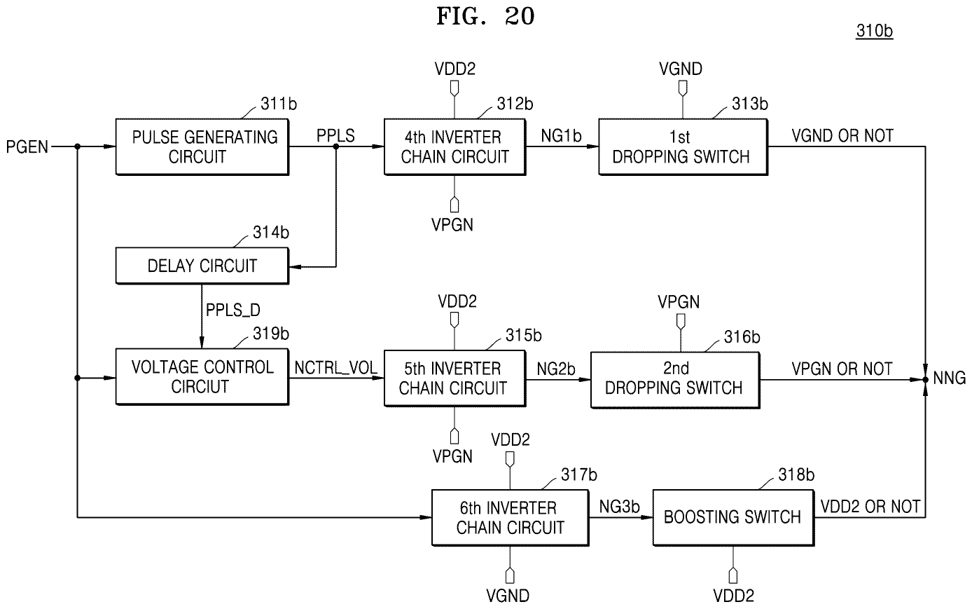

FIG. 20 is a block diagram showing another example of a dropping control circuit 310b according to the inventive concept.

Referring to FIG. 20, the dropping control circuit 310b may include a pulse generating circuit 311b, a fourth inverter chain circuit 312b, a first dropping switch 313b, a delay circuit 314b, a fifth inverter chain circuit 315b, a second dropping switch 316b, a sixth inverter chain circuit 317b, a boosting switch 318b, and a voltage control circuit 319b.

The pulse generating circuit 311b may output a pulse signal PPLS in response to the power gating enable signal PGEN. For example, when the power gating enable signal PGEN transitions from the logic low level to the logic high level, the pulse generating circuit 311b may output the pulse signal PPLS having the logic high level.

Each of the fourth inverter chain circuit 312b, the fifth inverter chain circuit 315b, and the sixth inverter chain circuit 317b may include a plurality of inverter circuits connected to each other in series.

Here, a positive power supply terminal of each of inverter circuits of the fourth inverter chain circuit 312b and the fifth inverter chain circuit 315b may be connected to the line of the second power supply voltage VDD2, and a negative power supply terminal of each of the inverter circuits of the fourth inverter chain circuit 312b and the fifth inverter chain circuit 315b may be connected to the line of the negative power gating voltage VPGN. The fourth inverter chain circuit 312b and the fifth inverter chain circuit 315b may output the second power supply voltage VDD2 or the negative power gating voltage VPGN according to a logic level of an input signal. A positive power supply terminal of each of inverter circuits of the sixth inverter chain circuit 317b may be connected to the line of the second power supply voltage VDD2, and a negative power supply terminal of each of the inverter circuits of the sixth inverter chain circuit 317b may be connected to the line of the ground voltage VGND. The sixth inverter chain circuit 317b may output the second power supply voltage VDD2 or the ground voltage VGND according to a logic level of an input signal.

In some embodiments, unlike that shown in FIG. 20, the negative power supply terminal of each of the inverter circuits of the sixth inverter chain circuit 317b may be connected to the line of the negative power gating voltage VPGN.

The fourth inverter chain circuit 312b may receive the pulse signal PPLS as an input signal and output the second power supply voltage VDD2 or the negative power gating voltage VPGN as a first power gating signal NG1b according to the logic level of the pulse signal PPLS.

The fifth inverter chain circuit 315b may receive a voltage control signal NCTRL_VOL as an input signal and output the second power supply voltage VDD2 or the negative power gating voltage VPGN as a second power gating signal NG2b according to the logic level of the voltage control signal NCTRL_VOL.

The sixth inverter chain circuit 317b may receive the power gating enable signal PGEN as an input signal and output the second power supply voltage VDD2 or the ground voltage VGND as a third power gating signal NG3b according to the logic level of the power gating enable signal PGEN.

The first dropping switch 313b may be connected between the line of the ground voltage VGND and the node NNG. The first dropping switch 313b may be turned on or off in response to the first power gating signal NG1b. For example, the first dropping switch 313b may be turned on in response to the first power gating signal NG1b having the second power supply voltage VDD2, and accordingly, the line of the ground voltage VGND may be connected to the node NNG. Also, the first dropping switch 313b may be turned off in response to the first power gating signal NG1b having the level of the negative power gating voltage VPGN, and accordingly, the line of the ground voltage VGND may be disconnected from the node NNG.

The second dropping switch 316b may be connected between the line of the negative power gating voltage VPGN and the node NNG. The second dropping switch 316b may be turned on or off in response to the second power gating signal NG2b. For example, the second dropping switch 316b may be turned on in response to the second power gating signal NG2b having the second power supply voltage VDD2, and accordingly, the line of the negative power gating voltage VPGN may be connected to the node NNG. Also, the second dropping switch 316b may be turned off in response to the second power gating signal NG2b having the level of the negative power gating voltage VPGN, and accordingly, the line of the negative power gating voltage VPGN may be disconnected from the node NNG.

The boosting switch 318b may be connected between the line of the second power supply voltage VDD2 and the node NNG. The boosting switch 318b may be turned on or off in response to the third power gating signal NG3b. For example, the boosting switch 318b may be turned on in response to the third power gating signal NG3b having the level of the ground voltage VGND, and accordingly, the line of the second power supply voltage VDD2 may be connected to the node NNG. Also, the boosting switch 318b may be turned off in response to the third power gating signal NG3b having the level of the second power supply voltage VDD2, and accordingly, the line of the second power supply voltage VDD2 may be disconnected from the node NNG.

The delay circuit 314b may receive the pulse signal PPLS as an input signal and output a delayed pulse signal PPLS_D. Here, the delayed pulse signal PPLS_D may represent a pulse signal having a form in which a period of time having a specific logic level of the pulse signal PPLS has been increased by a predetermined amount of time. For example, when the pulse signal PPLS has a logic high level, the delayed pulse signal PPLS_D may represent a pulse signal having a form in which a period of time having the logic high level of the pulse signal PPLS has been increased by a predetermined amount of time.

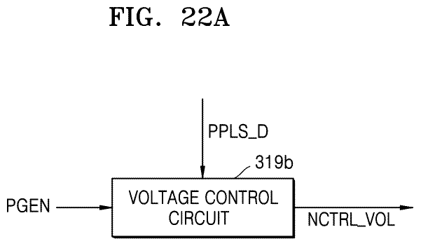

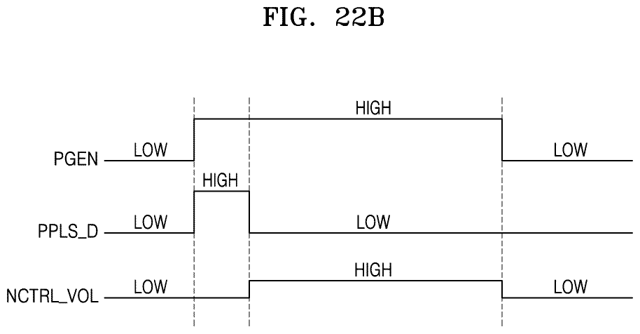

The voltage control circuit 319b may receive the power gating enable signal PGEN and the delayed pulse signal PPLS_D as input signals and may output the voltage control signal NCTRL_VOL. The voltage control signal NCTRL_VOL of the voltage control circuit 319b is described in detail with reference to FIG. 22.

Compared to the dropping control circuit 310a of FIG. 10, the dropping control circuit 310b of FIG. 20 may not include the short protection circuit 316a. Instead, the dropping control circuit 310b may include two voltage dropping paths for lowering the voltage of the node NNG and one voltage boosting path for raising the voltage of the node NNG, thereby preventing a short-circuit between voltage lines.

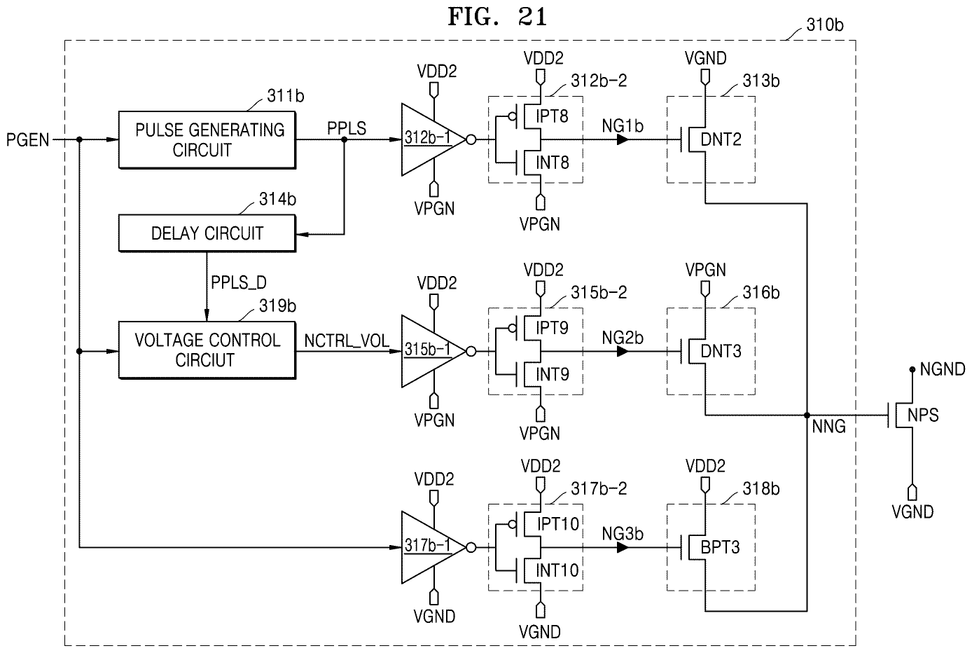

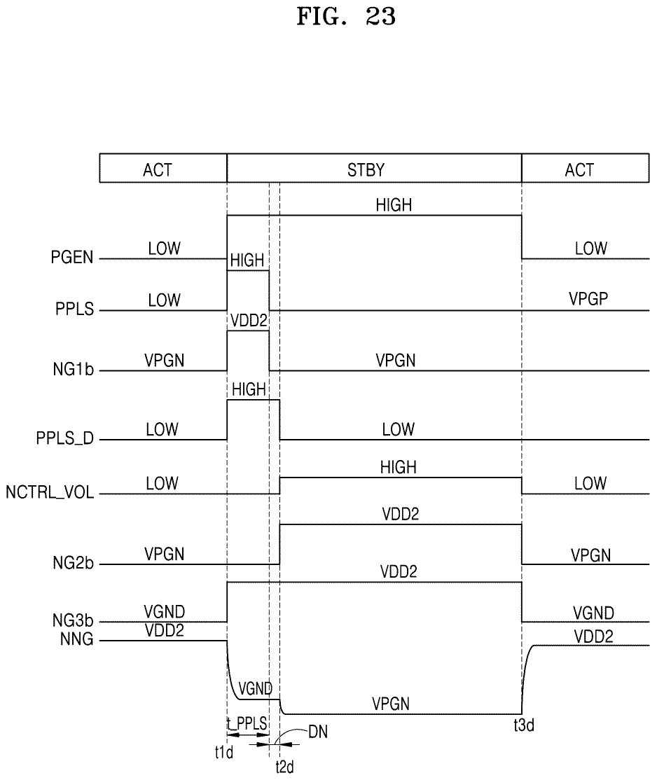

FIG. 21 is a diagram showing an equivalent circuit according to an example of the dropping control circuit 310b of FIG. 20. FIGS. 22A and 22B are diagrams illustrating the voltage control circuit 319b of FIG. 20. FIG. 23 is a timing chart of the dropping control circuit 310b of FIG. 21.

The pulse generating circuit 311b of FIGS. 20 and 21 may correspond to the pulse generating circuit 311a of FIG. 12, the delay circuit 314b of FIGS. 20 and 21 may correspond to the delay circuit 314a of FIG. 13, and repeated descriptions thereof are omitted.

Prior to describing the dropping control circuit 310b of FIG. 21, the voltage control circuit 319b is described first with reference to FIGS. 22A and 22B.

Referring to FIG. 22A, the voltage control circuit 319b may receive the power gating enable signal PGEN and the delayed pulse signal PPLS_D as input signals and may output the voltage control signal NCTRL_VOL.

Referring to FIG. 22B, when the logic level of the power gating enable signal PGEN is logic low, the voltage control circuit 319b may output the voltage control signal NCTRL_VOL having the logic low level, irrespective of the logic level of the delayed pulse signal PPLS_D.

Referring to FIG. 22B, when the logic level of the power gating enable signal PGEN is logic high, the voltage control circuit 319b may output the voltage control signal NCTRL_VOL, based on the logic level of the delayed pulse signal PPLS_D. When the logic level of the power gating enable signal PGEN is logic high and the logic level of the delayed pulse signal PPLS_D is logic high, the voltage control circuit 319b may output the voltage control signal NCTRL_VOL having the logic low level. When the logic level of the power gating enable signal PGEN is logic high and the logic level of the delayed pulse signal PPLS_D is logic low, the voltage control circuit 319b may output the voltage control signal NCTRL_VOL having the logic high level.

Returning to FIG. 21, the dropping control circuit 310b of FIG. 21 is described with reference to FIGS. 21 and 23.

Referring to FIG. 21, each of the fourth inverter chain circuit 312b, the fifth inverter chain circuit 315b, and the sixth inverter chain circuit 317b may include two inverter circuits. However, the embodiment is not limited thereto, and the number of inverter circuits in the fourth to sixth inverter chain circuits 312b, 315b, and 317b may vary according to embodiments. The number of inverter circuits may be determined by considering a response speed or power consumption, etc., according to characteristics of current in total circuits. Also, the inverter circuit may be formed as the CMOS transistor and configured such that the NMOS transistor and the PMOS transistor in the inverter circuit operate in a complementary manner.

Referring to FIG. 21, the fourth inverter chain circuit 312b may include an inverter circuit 312b-1 and an inverter circuit 312b-2. The inverter circuit 312b-1 and the inverter circuit 312b-2 may be connected to each other in series. The inverter circuit 312b-1 may receive the pulse signal PPLS as an input signal, and the inverter circuit 312b-2 may output the second power supply voltage VDD2 or the negative power gating voltage VPGN as the first power gating signal NG1b according to the logic level of the pulse signal PPLS.

Referring to FIG. 21, the inverter circuit 312b-2 may include a PMOS transistor IPT8 and an NMOS transistor INT8. A source terminal of the PMOS transistor IPT8 may be connected to the line of the second power supply voltage VDD2, a drain terminal of the PMOS transistor IPT8 may be connected to a gate terminal of an NMOS transistor DNT2 and a drain terminal of the NMOS transistor INT8, and a gate terminal of the PMOS transistor IPT8 may be connected to an output terminal of the inverter circuit 312b-1. A source terminal of the NMOS transistor INT8 may be connected to the line of the negative power gating voltage VPGN, the drain terminal of the NMOS transistor INT8 may be connected to the gate terminal of the NMOS transistor DNT2 and the drain terminal of the PMOS transistor IPT8, and a gate terminal of the NMOS transistor INT8 may be connected to the output terminal of the inverter circuit 312b-1.

Referring to FIG. 21, the fifth inverter chain circuit 315b may include an inverter circuit 315b-1 and an inverter circuit 315b-2. The inverter circuit 315b-1 and the inverter circuit 315b-2 may be connected to each other in series. The inverter circuit 315b-1 may receive the voltage control signal NCTRL_VOL as an input signal, and the inverter circuit 315b-2 may output the second power supply voltage VDD2 or the negative power gating voltage VPGN as the second power gating signal NG2b according to the logic level of the voltage control signal NCTRL_VOL.

Referring to FIG. 21, the inverter circuit 315b-2 may include a PMOS transistor IPT9 and an NMOS transistor INT9. A source terminal of the PMOS transistor IPT9 may be connected to the line of the second power supply voltage VDD2, a drain terminal of the PMOS transistor IPT9 may be connected to a gate terminal of an NMOS transistor DNT3 and a drain terminal of the NMOS transistor INT9, and a gate terminal of the PMOS transistor IPT9 may be connected to an output terminal of the inverter circuit 315b-1. A source terminal of the NMOS transistor INT9 may be connected to the line of the negative power gating voltage VPGN, the drain terminal of the NMOS transistor INT9 may be connected to the gate terminal of the NMOS transistor DNT3 and the drain terminal of the PMOS transistor IPT9, and a gate terminal of the NMOS transistor INT9 may be connected to the output terminal of the inverter circuit 315b-1.

Referring to FIG. 21, the sixth inverter chain circuit 317b may include an inverter circuit 317b-1 and an inverter circuit 317b-2. The inverter circuit 317b-1 and the inverter circuit 317b-2 may be connected to each other in series. The inverter circuit 317b-1 may receive the power gating enable signal PGEN as an input signal, and the inverter circuit 317b-2 may output the second power supply voltage VDD2 or the ground voltage VGND as the third power gating signal NG3b according to the logic level of the power gating enable signal PGEN.

Referring to FIG. 21, the inverter circuit 317b-2 may include a PMOS transistor IPT10 and an NMOS transistor INT10. A source terminal of the PMOS transistor IPT10 may be connected to the line of the second power supply voltage VDD2, a drain terminal of the PMOS transistor IPT10 may be connected to a gate terminal of a PMOS transistor BPT3 and a drain terminal of the NMOS transistor INT10, and a gate terminal of the PMOS transistor IPT10 may be connected to an output terminal of the inverter circuit 317b-1. A source terminal of the NMOS transistor INT10 may be connected to the line of the ground voltage VGND, the drain terminal of the NMOS transistor INT10 may be connected to the gate terminal of the PMOS transistor BPT3 and the drain terminal of the PMOS transistor IPT10, and a gate terminal of the NMOS transistor INT10 may be connected to the output terminal of the inverter circuit 317b-1.

Referring to FIG. 21, the first dropping switch 313b may include the NMOS transistor DNT2. The NMOS transistor DNT2 may be connected between the line of the ground voltage VGND and the node NNG. The NMOS transistor DNT2 may be turned on or off in response to the first power gating signal NG1b. For example, the NMOS transistor DNT2 may be turned on in response to the first power gating signal NG1b having the level of the second power supply voltage VDD2, and accordingly, the line of the ground voltage VGND may be connected to the node NNG. Also, the NMOS transistor DNT2 may be turned off in response to the first power gating signal NG1b having the level of the negative power gating voltage VPGN, and accordingly, the line of the ground voltage VGND may be disconnected from the node NNG.

Referring to FIG. 21, the second dropping switch 316b may include the NMOS transistor DNT3. The NMOS transistor DNT3 may be connected between the line of the negative power gating voltage VPGN and the node NNG. The NMOS transistor DNT3 may be turned on or off in response to the second power gating signal NG2b. For example, the NMOS transistor DNT3 may be turned on in response to the second power gating signal NG2b having the level of the second power supply voltage VDD2, and accordingly, the line of the negative power gating voltage VPGN may be connected to the node NNG. Also, the NMOS transistor DNT3 may be turned off in response to the second power gating signal NG2b having the level of the negative power gating voltage VPGN, and accordingly, the line of the negative power gating voltage VPGN may be disconnected from the node NNG.

Referring to FIG. 21, the boosting switch 318b may include the PMOS transistor BPT3. The PMOS transistor BPT3 may be connected between the line of the second power supply voltage VDD2 and the node NNG. The PMOS transistor BPT3 may be turned on or off in response to the third power gating signal NG3b. For example, the PMOS transistor BPT3 may be turned on in response to the third power gating signal NG3b having the level of the ground voltage VGND, and accordingly, the line of the second power supply voltage VDD2 may be connected to the node NNG. Also, the PMOS transistor BPT3 may be turned off in response to the third power gating signal NG3b having the level of the second power supply voltage VDD2, and accordingly, the line of the second power supply voltage VDD2 may be disconnected from the node NNG.

Referring to FIG. 23, the diagram shows a timing chart of the active mode ACT and the standby mode STBY. Referring to FIGS. 21 and 23, prior to a point in time t1d, the control logic circuit 121 may output the power gating enable signal PGEN having the logic low level in response to the command CMD indicating the active mode ACT. From the point in time t1d to a point in time t3d, the control logic circuit 121 may output the power gating enable signal PGEN having the logic high level in response to the command CMD indicating the standby mode STBY. After the point in time t3d, the control logic circuit 121 may output the power gating enable signal PGEN having the logic low level in response to the command CMD indicating the active mode ACT. Hereafter, the operation of the dropping control circuit 310b from the point in time t1d to the point in time t3d is described.

From the point in time t1d, the pulse generating circuit 311b may output the pulse signal PPLS having the logic high level during the pulse time t_PPLS in response to the power gating enable signal PGEN having the logic high level. After the pulse time t_PPLS, the pulse generating circuit 311b may output the pulse signal PPLS having the logic low level.

Also, from the point in time t1d, the inverter circuit 312b-2 of the fourth inverter chain circuit 312b may output the first power gating signal NG1b having the level of the second power supply voltage VDD2 during the pulse time t_PPLS in response to the pulse signal PPLS having the logic high level. After the pulse time t_PPLS, the inverter circuit 312b-2 of the fourth inverter chain circuit 312b may output the first power gating signal NG1b having the level of the negative power gating voltage VPGN in response to the pulse signal PPLS having the logic low level.

Also, from the point in time t1d, the delay circuit 314b may output the delayed pulse signal PPLS_D having the logic high level during the pulse time t_PPLS and the delay time DN in response to the pulse signal PPLS having the logic high level. From a point in time t2d after the pulse time t_PPLS and the delay time DN, the delay circuit 314b may output the delayed pulse signal PPLS_D having the logic low level.

Also, from the point in time t1d to the point in time t2d, the logic level of the power gating enable signal PGEN is logic high, and the logic level of the delayed pulse signal PPLS_D is logic high, as described with reference to FIG. 22. Therefore, the voltage control circuit 319b may output the voltage control signal NCTRL_VOL having the logic low level. Also, after the point in time t2d, the logic level of the power gating enable signal PGEN is logic high, and the logic level of the delayed pulse signal PPLS_D is logic low, as described with reference to FIG. 22. Therefore, the voltage control circuit 319b may output the voltage control signal NCTRL_VOL having the logic high level.

Also, from the point in time t1d to the point in time t2d, the inverter circuit 315b-2 of the fifth inverter chain circuit 315b may output the second power gating signal NG2b having the level of the negative power gating voltage VPGN in response to the voltage control signal NCTRL_VOL having the logic low level. Also, after the point in time t2d, the inverter circuit 315b-2 of the fifth inverter chain circuit 315b may output the second power gating signal NG2b having the level of the second power supply voltage VDD2 in response to the voltage control signal NCTRL_VOL having the logic high level.

Also, from the point in time t1d, the inverter circuit 317b-2 of the sixth inverter chain circuit 317b may output the third power gating signal NG3b having the level of the second power supply voltage VDD2 in response to the power gating enable signal PGEN having the logic high level.

In addition, during the pulse time t_PPLS from the point in time t1d, the NMOS transistor DNT3 is turned on in response to the first power gating signal NG1b having the level of the second power supply voltage VDD2. Accordingly, the ground voltage VGND may be provided to the node NNG from the line of the ground voltage VGND.

After the pulse time t_PPLS, the NMOS transistor DNT3 is turned off in response to the first power gating signal NG1b having the level of the negative power gating voltage VPGN. Accordingly, the ground voltage VGND may not be supplied to the node NNG from the line of the ground voltage VGND. Here, during the delay time DN after the pulse time t_PPLS, the node NNG may be disconnected from all of the line of the second power supply voltage VDD2, the line of the negative power gating voltage VPGN, and the line of the ground voltage VGND, and accordingly, a short-circuit between the line of the second power supply voltage VDD2, the line of the negative power gating voltage VPGN, and the line of the ground voltage VGND may be prevented.

From the point in time t2d after the pulse time t_PPLS and the delay time DN, the NMOS transistor DNT3 is turned on in response to the second power gating signal NG2b having the level of the second power supply voltage VDD2. Accordingly, the negative power gating voltage VPGN may be provided to the node NNG from the line of the negative power gating voltage VPGN.

As described above, according to the inventive concept, the voltage level of the node NNG is not lowered to the negative power gating voltage VPGN at once, but is lowered to the ground voltage VGND in an intermediate stage and then lowered to the negative power gating voltage VPGN. This may reduce the power consumed by the power gating operation of the second power gating circuit 300.

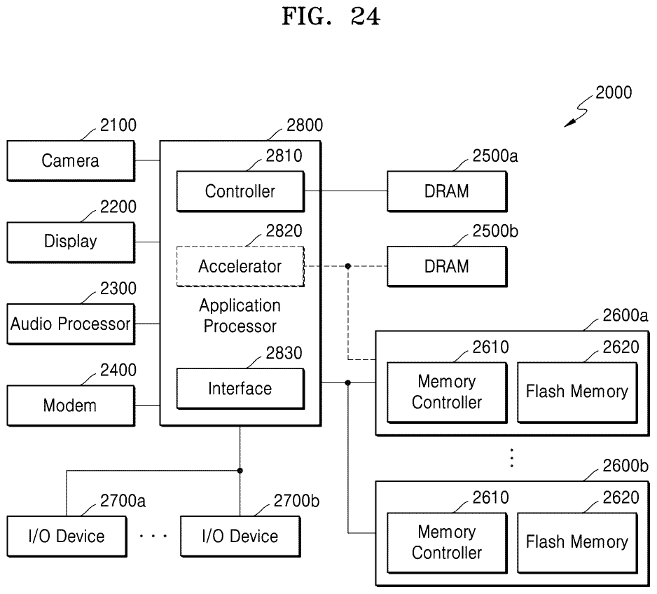

FIG. 24 is a block diagram of a system 2000 and illustrates an electronic product including a memory device according to embodiments.

As shown in FIG. 24, the system 2000 may include a camera 2100, a display 2200, an audio processor 2300, a modem 2400, DRAM 2500a and 2500b, flash memory 2600a and 2600b, input/output (I/O) devices 2700a and 2700b, and an application processor 2800 (hereinafter referred to as “AP”). The system 2000 may be provided as a laptop computer, a mobile phone, a smart phone, a tablet personal computer (PC), a wearable device, a healthcare device, or an IoT device. In addition, the system 2000 may be provided as a server or a PC.

The camera 2100 may capture still images or moving images under control by a user, and store the captured image/video data or transmit the data to the display 2200. The audio processor 2300 may process audio data in contents of the flash memory 2600a and 2600b or a network. The modem 2400 modulates and transmits signals to transmit and receive wired/wireless data, and the modulated and transmitted signals may be demodulated and restored to original signals at a reception side. The I/O devices 2700a and 2700b may include devices that provide digital input and/or output functions, such as a universal serial bus (USB) or storage, a digital camera, a secure digital (SD) card, a digital versatile disc (DVD), a network adapter, and a touch screen.

The AP 2800 may control all operations of the system 2000. The AP 2800 may include a control block 2810, an accelerator block or an accelerator chip 2820, and an interface block 2830. The AP 2800 may control the display 2200 so that some contents stored in the flash memory 2600a and 2600b are displayed on the display 2200. When a user input is received via the I/O devices 2700a and 2700b, the AP 2800 may perform a control operation in response to the user input. The AP 2800 may include the accelerator block, which is dedicated circuit for computing artificial intelligence (AI) data, or may have the accelerator chip 2820 separate from the AP 2800. The accelerator block or the accelerator chip 2820 may be further equipped with the DRAM 2500b. An accelerator represents a function block specialized in performing a particular function of the AP 2800, and the accelerator may include a graphics processing unit (GPU) that is a function block specialized in processing graphic data, a neural processing unit (NPU) that is a block specialized in performing AI computation and inference, and a data processing unit (DPU) that is a block specialized in data transmission.

The system 2000 may include the plurality of DRAM 2500a and 2500b. The AP 2800 may control the DRAM 2500a and 2500b by setting a mode register (MRS) and commands conforming to Joint Electron Device Engineering Council (JEDEC) standards, or may perform communication by establishing DRAM interface protocols to utilize vendor-specific functions, such as low voltage/high speed/reliability, and cyclic redundancy check (CRC)/error correction code (ECC) functions. For example, the AP 2800 may communicate with the DRAM 2500a over an interface conforming to JEDEC standards, such as low power double data rate 4th generation (LPDDR4) and low power double data rate 5th generation (LPDDR5), and the accelerator block or the accelerator chip 2820 may perform communication by establishing a new DRAM interface protocol to control the DRAM 2500b for an accelerator that has a higher bandwidth than the DRAM 2500a.

Only the DRAM 2500a and 2500b are shown in FIG. 24, but the embodiment is not limited thereto. Any memory may be used, such as PRAM, SRAM, MRAM, ReRAM, FeRAM, and hybrid RAM memory, as long as such memory satisfies the bandwidth, response speed, and voltage requirements of the AP 2800 or the accelerator chip 2820. The DRAM 2500a and 2500b have relatively less latency and bandwidth than the I/O devices 2700a and 2700b or the flash memory 2600a and 2600b. The DRAM 2500a and 2500b are initialized at a point in time when the system 2000 is powered on, and an operating system and application data are loaded thereon. The DRAM 2500a and 2500b may be used as temporary storage spaces for the operating system and application data or as execution spaces for various pieces of software code.

Arithmetic operations, such as addition, subtraction, multiplication, and division, vector operations, address operations, or fast Fourier transform (FFT) operations may be performed in the DRAM 2500a and 2500b. In addition, a function for execution used for inference may be performed inside the DRAM 2500a and 2500b. Here, the inference may be performed in a deep learning algorithm using an artificial neural network. The deep learning algorithm may include a training stage of training a model by using various pieces of data and an inference stage of identifying data by using the trained model. In an embodiment, the images captured by the user via the camera 2100 are signal-processed and stored in the DRAM 2500b, and the accelerator block or the accelerator chip 2820 may perform AI data calculation in which data is identified by using the data stored in the DRAM 2500b and the functions used in the inference.

The system 2000 may include a plurality of storage devices or the plurality of flash memory 2600a and 2600b having larger capacities than the DRAM 2500a and 2500b. The accelerator block or the accelerator chip 2820 may perform the training stage and the AI data calculation by using the flash memory 2600a and 2600b. In an embodiment, the flash memory 2600a and 2600b may include a memory controller 2610 and a flash memory device 2620, and an arithmetic unit provided in the memory controller 2610 may be used so that the training stage and the inference AI data calculation performed by the AP 2800 and/or the accelerator chip 2820 may be performed more efficiently. The flash memory 2600a and 2600b may store images captured by the camera 2100 or data transmitted via a data network. For example, augmented reality (AR)/virtual reality (VR), high definition (HD), or ultra high definition (UHD) contents may be stored.

In the system 2000, the DRAM 2500a and 2500b may perform an operating method of the memory device described with reference to FIG. 1 to FIG. 23.

While the inventive concept has been particularly shown and described with reference to embodiments thereof, it will be understood that various changes in form and details may be made therein without departing from the spirit and scope of the following claims.

What is claimed is:

1. A memory device comprising:
a memory cell array comprising memory cells;
a peripheral circuit configured to transmit a plurality of signals for writing or reading data to the memory cells;
a control logic circuit configured to output a power gating enable signal; and
a power gating circuit configured to, in response to the power gating enable signal, connect the peripheral circuit to or disconnect the peripheral circuit from a power supply voltage line,
wherein the power gating circuit comprises:
a positive power gating switch connected between the peripheral circuit and the power supply voltage line; and
a boosting control circuit configured to boost a gate voltage of the positive power gating switch to a first voltage level during a first stage and then boost the gate voltage of the positive power gating switch to a second voltage level higher than the first voltage level during a second stage after the first stage, in a standby mode.

2. The memory device of claim 1, wherein the first voltage level corresponds to a power supply voltage level, and the second voltage level corresponds to a positive power gating voltage level, and
the boosting control circuit comprises:
a pulse generating circuit configured to output a pulse signal in response to the power gating enable signal;
a first inverter chain circuit configured to output a first power gating signal having the positive power gating voltage level or a ground voltage level according to a logic level of the pulse signal;
a boosting switch connected between the power supply voltage line and a gate terminal of the positive power gating switch and configured to be turned on or off in response to the first power gating signal;
a second inverter chain circuit configured to output a second power gating signal having the positive power gating voltage level or the ground voltage level according to a logic level of the power gating enable signal;
a delay circuit configured to receive the pulse signal and output a delayed pulse signal or a delayed inverted pulse signal; and
a short protection circuit connected between the second inverter chain circuit and the gate terminal of the positive power gating switch and configured to be turned on or off in response to the delayed pulse signal or the delayed inverted pulse signal.

3. The memory device of claim 2, wherein, in the first stage, the boosting switch is configured to be turned on in response to the first power gating signal to connect the power supply voltage line to the gate terminal of the positive power gating switch.

4. The memory device of claim 3, wherein, between the first stage and the second stage, the power supply voltage line, a positive power gating voltage line, and the gate terminal of the positive power gating switch are configured to be disconnected from each other.

5. The memory device of claim 2, wherein, in the second stage, the short protection circuit is configured to be turned on in response to the delayed pulse signal or the delayed inverted pulse signal to connect a positive power gating voltage line to the gate terminal of the positive power gating switch.

6. The memory device of claim 1, wherein the first voltage level corresponds to a power supply voltage level, and the second voltage level corresponds to a positive power gating voltage level, and
the boosting control circuit comprises:
a pulse generating circuit configured to output a pulse signal in response to the power gating enable signal;
a first inverter chain circuit configured to output a first power gating signal having the positive power gating voltage level or a ground voltage level according to a logic level of the pulse signal;
a first boosting switch connected between the power supply voltage line and a gate terminal of the positive power gating switch and configured to be turned on or off in response to the first power gating signal;
a delay circuit configured to receive the pulse signal and output a delayed inverted pulse signal;
a voltage control circuit configured to receive the power gating enable signal and the delayed inverted pulse signal and output a voltage control signal;
a second inverter chain circuit configured to output a second power gating signal having the positive power gating voltage level or the ground voltage level according to a logic level of the voltage control signal;
a second boosting switch connected between a positive power gating voltage line and the gate terminal of the positive power gating switch and configured to be turned on or off in response to the second power gating signal;
a third inverter chain circuit configured to output a third power gating signal having the power supply voltage level or the ground voltage level according to a logic level of the power gating enable signal; and
a dropping switch connected between a ground voltage line and the gate terminal of the positive power gating switch and configured to be turned on or off in response to the third power gating signal.

7. The memory device of claim 6, wherein, in the first stage, the first boosting switch is configured to be turned on in response to the first power gating signal to connect the power supply voltage line to the gate terminal of the positive power gating switch.

8. The memory device of claim 7, wherein, between the first stage and the second stage, the power supply voltage line, the positive power gating voltage line, the ground voltage line, and the gate terminal of the positive power gating switch are configured to be disconnected from each other.

9. The memory device of claim 6, wherein, in the second stage, the second boosting switch is configured to be turned on in response to the second power gating signal to connect the positive power gating voltage line to the gate terminal of the positive power gating switch.

10. The memory device of claim 6, wherein the dropping switch is configured to be turned on in response to the third power gating signal to connect the ground voltage line to the gate terminal of the positive power gating switch, in an active mode.

11. A memory device comprising:
a memory cell array comprising memory cells;
a peripheral circuit configured to transmit a plurality of signals for writing or reading data to the memory cells;
a control logic circuit configured to output a power gating enable signal; and
a power gating circuit configured to, in response to the power gating enable signal, connect the peripheral circuit to or disconnect the peripheral circuit from a ground voltage line,
wherein the power gating circuit comprises:
a negative power gating switch connected between the peripheral circuit and the ground voltage line; and
a dropping control circuit configured to drop a gate voltage of the negative power gating switch to a first voltage level during a first stage and then drop the gate voltage of the negative power gating switch to a second voltage level lower than the first voltage level during a second stage after the first stage, in a standby mode.

12. The memory device of claim 11, wherein the first voltage level corresponds to a ground voltage level, and the second voltage level corresponds to a negative power gating voltage level, and
the dropping control circuit comprises:
a pulse generating circuit configured to output a pulse signal in response to the power gating enable signal;
a first inverter chain circuit configured to output a first power gating signal having the negative power gating voltage level or a power supply voltage level according to a logic level of the pulse signal;
a dropping switch connected between the ground voltage line and a gate terminal of the negative power gating switch and configured to be turned on or off in response to the first power gating signal;
a second inverter chain circuit configured to output a second power gating signal having the negative power gating voltage level or the power supply voltage level according to a logic level of the power gating enable signal;
a delay circuit configured to receive the pulse signal and output a delayed pulse signal or a delayed inverted pulse signal; and
a short protection circuit connected between the second inverter chain circuit and the gate terminal of the negative power gating switch and configured to be turned on or off in response to the delayed pulse signal or the delayed inverted pulse signal.

13. The memory device of claim 12, wherein, in the first stage, the dropping switch is configured to be turned on in response to the first power gating signal to connect the ground voltage line to the gate terminal of the negative power gating switch.

14. The memory device of claim 13, wherein, between the first stage and the second stage, the ground voltage line, a negative power gating voltage line, and the gate terminal of the negative power gating switch are configured to be disconnected from each other.

15. The memory device of claim 12, wherein, in the second stage, the short protection circuit is configured to be turned on in response to the delayed pulse signal or the delayed inverted pulse signal to connect a negative power gating voltage line to the gate terminal of the negative power gating switch.

16. The memory device of claim 11, wherein the first voltage level corresponds to a ground voltage level, and the second voltage level corresponds to a negative power gating voltage level, and
the dropping control circuit comprises:
a pulse generating circuit configured to output a pulse signal in response to the power gating enable signal;
a first inverter chain circuit configured to output a first power gating signal having the negative power gating voltage level or a power supply voltage level according to a logic level of the pulse signal;
a first dropping switch connected between the ground voltage line and a gate terminal of the negative power gating switch and configured to be turned on or off in response to the first power gating signal;
a delay circuit configured to receive the pulse signal and output a delayed pulse signal;
a voltage control circuit configured to receive the power gating enable signal and the delayed pulse signal and output a voltage control signal;
a second inverter chain circuit configured to output a second power gating signal having the negative power gating voltage level or the power supply voltage level according to a logic level of the voltage control signal;
a second dropping switch connected between a negative power gating voltage line and the gate terminal of the negative power gating switch and configured to be turned on or off in response to the second power gating signal;
a third inverter chain circuit configured to output a third power gating signal having the power supply voltage level or the ground voltage level according to a logic level of the power gating enable signal; and
a boosting switch connected between a power supply voltage line and the gate terminal of the negative power gating switch and configured to be turned on or off in response to the third power gating signal.

17. The memory device of claim 16, wherein in the first stage, the first dropping switch is configured to be turned on in response to the first power gating signal to connect the ground voltage line to the gate terminal of the negative power gating switch.

18. The memory device of claim 16, wherein, in the second stage, the second dropping switch is configured to be turned on in response to the second power gating signal to connect the negative power gating voltage line to the gate terminal of the negative power gating switch.

19. The memory device of claim 16, wherein the boosting switch is configured to be turned on in response to the third power gating signal to connect the power supply voltage line to the gate terminal of the negative power gating switch, in an active mode.

20. A memory system comprising:
a host device configured to transmit a command indicating a standby mode; and
a memory device configured to operate in the standby mode in response to the command,
wherein the memory device comprises:
a memory cell array comprising memory cells;
a peripheral circuit configured to transmit a plurality of signals for writing or reading data to the memory cells;
a control logic circuit configured to output a power gating enable signal in response to the command; and
a power gating circuit configured to, in response to the power gating enable signal, connect the peripheral circuit to or disconnect the peripheral circuit from a power supply voltage line,
wherein the power gating circuit comprises:
a positive power gating switch connected between the peripheral circuit and the power supply voltage line; and
a boosting control circuit configured to boost a gate voltage of the positive power gating switch to a first voltage level during a first stage and then boost the gate voltage of the positive power gating switch to a second voltage level higher than the first voltage level during a second stage after the first stage.
